(19) United States
(12) Patent Application Publication
(10) Pub. No.: US 2014/0246627 A1
(43) Pub. Date: Sep. 4, 2014

(54) ELECTROMAGNETIC WAVE ABSORPTION PLATE, AND COMPOSITION FOR SAME AND METHOD FOR MANUFACTURING SAME

(71) Applicant: AJINOMOTO CO., INC., Tokyo (JP)

(72) Inventors: Nobuo BAN, Kawasaki-shi (JP); Hiroki KOBAYASHI, Kawasaki-shi (JP)

(73) Assignee: AJINOMOTO CO., INC., Tokyo (JP)

(21) Appl. No.: 14/279,738

(22) Filed: May 16, 2014

Related U.S. Application Data
(63) Continuation of application No. PCT/JP2012/079695, filed on Nov. 15, 2012.

(30) Foreign Application Priority Data
Nov. 18, 2011 (JP) 2011-253309

(51) Int. Cl. H05K 9/00

(52) U.S. Cl. CPC H05K 9/0081
USPC 252/478

(57) ABSTRACT

A plurality of kinds of carbonized powders obtained by carbonizing a plant material at different carbonization temperatures are dispersed in a resin to form a composition for an electromagnetic wave absorbing plate. When an electromagnetic wave absorbing plate is formed using the composition, the d/λ value in a non-reflective state of the electromagnetic wave absorbing plate can be adjusted to fall within the predetermined range rather than at a single point, by adjusting each weight ratio of the plural kinds of carbonized powders.

### CROSS REFERENCES TO RELATED APPLICATIONS

This application is a continuation of International Patent Application No. PCT/JP2012/079695, filed on Nov. 15, 2012, and claims priority to Japanese Patent Application No. 2011-253309, filed on Nov. 18, 2011, both of which are incorporated herein by reference in their entireties.

### BACKGROUND OF THE INVENTION

1. Field of the Invention

The present invention relates to compositions for an electromagnetic wave absorbing plate, electromagnetic wave absorbing plates which use such a composition, and method of producing such an electromagnetic wave absorbing plate.

2. Discussion of the Background

Electromagnetic waves emitted from electronic equipment can exert an adverse influence on other electronic equipment. Therefore, an electromagnetic wave absorbers that absorb electromagnetic waves have been actively studied.

For example, JP-A-2002-368477, JP-A-2006-80502, and WO 2010/03582, all of which are incorporated herein by reference in their entireties, describe electromagnetic wave absorbers obtained from a composition containing a resin and vegetable carbon, bamboo charcoal, or a burned plant material. In addition, JP-A-2010-153833, which is incorporated herein by reference in its entirety, describes an electromagnetic wave absorber obtained from a composition containing a carbonized powder obtained by carbonizing a mixture of a woody material and a thermosetting resin, and an organic binder. However, none of JP-A-2002-368477, JP-A-2006-80502, WO 2010/03582, and JP-A-2010-153833 describes a technique for using plural kinds of carbonized powders with different carbonization temperatures in combination.

### SUMMARY OF THE INVENTION

In electromagnetic wave absorbing plates, an ideal electromagnetic wave absorption state free of reflection of an electromagnetic wave (which state is referred to as a “non-reflective state” in the present invention) is achieved at an intersection point of a curve of a graph showing the relationship between the real part and the imaginary part of the relative dielectric constant (relative permittivity), and the first no-reflection curve. In this non-reflective state, the d/λ value, wherein d is a thickness of an electromagnetic wave absorbing plate and λ is a wavelength of the electromagnetic wave to be absorbed, is determined as one point.

Therefore, in a process to achieve a non-reflective state, λ and d cannot be changed independently from each other. In other words, when wavelength λ of an electromagnetic wave to be absorbed is changed, the thickness d of the electromagnetic wave absorbing plate that achieves the non-reflective state is determined in accordance with the changed wavelength. Conversely, when the thickness d of the electromagnetic wave absorbing plate is changed, the wavelength λ of the electromagnetic wave that achieves the non-reflective state is determined in accordance with the changed thickness. Therefore, to achieve a non-reflective state, one of λ and d is restricted, thereby posing a problem.

Accordingly, it is one object of the present invention to provide novel methods of producing a composition for an electromagnetic wave absorbing plate and an electromagnetic wave absorbing plate, which can adjust the d/λ value in a non-reflective state of an electromagnetic wave absorbing plate to fall within the predetermined range rather than to one point.

It is another object of the present invention to provide novel compositions for an electromagnetic wave absorbing plate.

It is another object of the present invention to provide novel electromagnetic wave absorbing plates which use such a composition.

These and other objects, which will become apparent during the following detailed description, have been achieved by the following:

(1) A composition for an electromagnetic wave absorbing plate, which comprises a carbonized powder and a resin, wherein plural kinds of carbonized powders obtained by carbonizing a plant material at different carbonization temperatures are dispersed in the resin.

(2) The composition of the aforementioned (1), wherein each of the aforementioned plural kinds of carbonized powders has a weight ratio adjusted according to a d/λ value in a non-reflective state, wherein d is the thickness of an electromagnetic wave absorbing plate formed from the aforementioned composition, and λ is the wavelength of an electromagnetic wave to be absorbed by the aforementioned electromagnetic wave absorbing plate, such that the aforementioned electromagnetic wave absorbing plate is in the non-reflective state.

(3) The composition of the aforementioned (1) or (2), wherein the aforementioned plural kinds of carbonized powders are 3 kinds of carbonized powders obtained by carbonizing a plant material at the carbonization temperatures of the following (A)-(C):

(A) less than 850° C.,

(B) not less than 850° C. and less than 950° C.,

(C) not less than 950° C.

(4) The composition of the aforementioned (3), wherein the carbonization temperatures of the aforementioned (A)-(C) are

(A) not less than 400° C. and not more than 800° C.,

(B) not less than 850° C. and not more than 930° C.,

(C) not less than 950° C. and not more than 3000° C.

(5) The composition of the aforementioned (1) or (2), wherein the aforementioned plural kinds of carbonized powders are 3 or 4 kinds of carbonized powders selected from 4 kinds of carbonized powders obtained by carbonizing a plant material at the carbonization temperatures of the following (a)-(d):

(a) not less than 550° C. and less than 650° C.,

(b) not less than 650° C. and less than 800° C.,

(c) not less than 800° C. and less than 1000° C.,

(d) not less than 1000° C. and not more than 1200° C.

(6) The composition of the aforementioned (5), wherein the carbonization temperatures of the aforementioned (a)-(d) are

(a) not less than 550° C. and not more than 630° C.,

(b) not less than 650° C. and not more than 730° C.,

(c) not less than 850° C. and less than 1000° C.,

(d) not less than 1100° C. and not more than 1200° C.

(7) The composition of any one of the aforementioned (1) to (6), wherein the aforementioned plant material is humus.

(8) An electromagnetic wave absorbing plate formed from the composition of any one of the aforementioned (1) to (7).

(9) The electromagnetic wave absorbing plate of the aforementioned (8), wherein the electromagnetic wave to be absorbed by the electromagnetic wave absorbing plate has a wavelength λ of 100 μm-1 m.

(10) A production method of an electromagnetic wave absorbing plate, comprising steps of: mixing a resin and plural kinds of carbonized powders obtained by carbonizing a plant material at different carbonization temperatures to give a composition wherein the plural kinds of carbonized powders are dispersed in the resin; and forming the aforementioned composition to give the electromagnetic wave absorbing plate.

(11) The production method of the aforementioned (10), wherein a weight ratio of each of the aforementioned plural kinds of carbonized powders is adjusted according to a d/λ value in a non-reflective state, wherein d is the thickness of an electromagnetic wave absorbing plate formed from the aforementioned composition, and λ is the wavelength of an electromagnetic wave to be absorbed by the aforementioned electromagnetic wave absorbing plate, such that the aforementioned electromagnetic wave absorbing plate is in the non-reflective state.

(12) The production method of the aforementioned (10) or (11), wherein the aforementioned plural kinds of carbonized powders are 3 kinds of carbonized powders obtained by carbonizing a plant material at the carbonization temperatures of the following (A)-(C):

(A) less than 850° C.,

(B) not less than 850° C. and less than 950° C.,

(C) not less than 950° C.

(13) The production method of the aforementioned (12), wherein the carbonization temperatures of the aforementioned (A)-(C) are

(A) not less than 400° C. and not more than 800° C.,

(B) not less than 850° C. and not more than 930° C.,

(C) not less than 950° C. and not more than 3000° C.

(14) The production method of the aforementioned (10) or (11), wherein the aforementioned plural kinds of carbonized powders are 3 or 4 kinds of carbonized powders selected from 4 kinds of carbonized powders obtained by carbonizing a plant material at the carbonization temperatures of the following (a)-(d):

(a) not less than 550° C. and less than 650° C.,

(b) not less than 650° C. and less than 800° C.,

(c) not less than 800° C. and less than 1000° C.,

(d) not less than 1000° C. and not more than 1200° C.

(15) The production method of the aforementioned (14), wherein the carbonization temperatures of the aforementioned (a)-(d) are

(a) not less than 550° C. and not more than 630° C.,

(b) not less than 650° C. and not more than 730° C.,

(c) not less than 850° C. and less than 1000° C.,

(d) not less than 1100° C. and not more than 1200° C.

(16) The production method of any one of the aforementioned (10) to (15), wherein an electromagnetic wave to be absorbed by the aforementioned electromagnetic wave absorbing plate has a wavelength λ of 100 μm-1 m.

(17) The production method of any one of the aforementioned (10) to (16), wherein the wavelength λ of the aforementioned electromagnetic wave is fixed at a given value, and

the thickness d of an electromagnetic wave absorbing plate to achieve a non-reflective state relative to the aforementioned wavelength λ is changed by changing each weight ratio of the aforementioned 3 kinds of carbonized powders.

(18) The production method of any one of the aforementioned (10) to (18), wherein the thickness d of an electromagnetic wave absorbing plate is fixed at a given value, and

the wavelength λ of the aforementioned electromagnetic wave which achieves a non-reflective state relative to the aforementioned thickness d is changed by changing each weight ratio of the aforementioned 3 kinds of carbonized powders.

(19) The production method of any one of the aforementioned (10) to (18), wherein the aforementioned plant material is humus.

In the present invention, the “composition for an electromagnetic wave absorbing plate” means a “composition for producing an electromagnetic wave absorbing plate”. In the following, “the composition for an electromagnetic wave absorbing plate of the present invention” and “the production method of the electromagnetic wave absorbing plate of the present invention” are sometimes referred to as “the composition of the present invention” and “the production method of the present invention”, and “carbonized powder and by carbonizing a plant material at carbonization temperature (A)” and the like are sometimes referred to as “carbonized powder (A)” and the like.

According to the present invention, the d/λ value in a non-reflective state of the electromagnetic wave absorbing plate can be adjusted to fall within the predetermined range rather than one point.

### BRIEF DESCRIPTION OF THE DRAWINGS

A more complete appreciation of the invention and many of the attendant advantages thereof will be readily obtained as the same become better understood by reference to the following detailed description when considered in connection with the accompanying drawings, wherein:

FIG. 1 is a graph illustrating the first no-reflection curve (cited from FIG. 3.3 on page 46 of Osamu Hashimoto, “Denpakyushuban no hanashi (The story of radio wave absorbing plate)” Nikkan Kogyo Shimbun Ltd., which is incorporated herein by reference in its entirety).

FIG. 2 is a graph showing the relationship between d/λ of the first no-reflection curve and relative dielectric constant (real part).

FIG. 3 is a graph showing the relationship between d/λ of the first no-reflection curve and relative dielectric constant (imaginary part).

FIG. 4 is a graph showing the relationship between the weight ratio (%) of carbonized powder (B) and relative dielectric constant of the electromagnetic wave absorbing plate (II) containing 2 kinds of carbonized powders (A) and (B). FIG. 4-FIG. 12 are graphs illustrating the embodiments of the present invention, and FIG. 13-FIG. 21 are graphs illustrating preferable embodiments of the present invention.

FIG. 5 is a graph showing the relationship between the weight ratio (%) of carbonized powder (C) and relative dielectric constant of the electromagnetic wave absorbing plate (III) containing 2 kinds of carbonized powders (A) and (C).

FIG. 6 is a graph showing the relationship between a real part and an imaginary part of a relative dielectric constant of an electromagnetic wave absorbing plate (carbonized powder content: 130 phr) using carbonized powders with different carbonization temperatures.

FIG. 7 shows a graph showing the relationship between a real part and an imaginary part of a relative dielectric constant of the electromagnetic wave absorbing plate (II) containing 2 kinds of carbonized powders (A) and (B), a graph showing the relationship between a real part and an imaginary part of a relative dielectric constant of the electromagnetic wave absorbing plate (III) containing carbonized powders (A) and (C), and the first no-reflection curve (carbonization temperature of (A): 600° C., carbonization temperature of (B): 900° C., carbonization temperature of (C): 1150° C., the total amount of carbonized powders in electromagnetic wave absorbing plate (II) and (III): 130 phr for both).

FIG. 8 is a graph showing the relationship between the weight ratio (%) of carbonized powder (A) and relative dielectric constant due to carbonized powder (A) of the electromagnetic wave absorbing plate (II) containing 2 kinds of carbonized powders (A) and (B).

FIG. 9 is a graph showing the relationship between the weight ratio (%) of carbonized powder (B) and relative dielectric constant due to carbonized powder (B) of the electromagnetic wave absorbing plate (II) containing 2 kinds of carbonized powders (A) and (B).

FIG. 10 is a graph showing the relationship between the weight ratio (%) of carbonized powder (C) and relative dielectric constant due to carbonized powder (C) of the electromagnetic wave absorbing plate (III) containing 2 kinds of carbonized powders (A) and (C).

FIG. 11 is a graph showing the relationship between the measured value and the calculated value of the relative dielectric constant (real part) of the electromagnetic wave absorbing plate (I) containing 3 kinds of carbonized powders (A)-(C).

FIG. 12 is a graph showing the relationship between the measured value and the calculated value of the relative dielectric constant (imaginary part) of the electromagnetic wave absorbing plate (I) containing 3 kinds of carbonized powders (A)-(C).

FIG. 13 is a graph showing the relationship between the weight ratio (%) of carbonized powder (b) and relative dielectric constant of the electromagnetic wave absorbing plate (IIβ) containing 2 kinds of carbonized powders (a) and (b).

FIG. 14 is a graph showing the relationship between the weight ratio (%) of carbonized powder (c) and relative dielectric constant of the electromagnetic wave absorbing plate (IIIβ) containing 2 kinds of carbonized powders (a) and (c).

FIG. 15 is a graph showing the relationship between a real part and an imaginary part of a relative dielectric constant of an electromagnetic wave absorbing plate (carbonized powder content: 130 phr) using carbonized powders with different carbonization temperatures.

FIG. 16 is a graph showing a curve showing the relationship between each real part and an imaginary part of respective relative dielectric constants of 3 kinds of electromagnetic wave absorbing plates (electromagnetic wave absorbing plate (IIβ) containing carbonized powders (a), (b), electromagnetic wave absorbing plate (IIIβ) containing carbonized powders (a), (c), and electromagnetic wave absorbing plate (IVβ) containing carbonized powders (a), (d)), and the first no-reflection curve (carbonization temperature of (a): 600° C., carbonization temperature of (b): 670° C., carbonization temperature of (c): 900° C., carbonization temperature of (d): 1150° C., the total amount of respective carbonized powders in electromagnetic wave absorbing plates (IIβ), (IIIβ) and (IVβ) is always 130 phr).

FIG. 17 is a graph showing the relationship between the weight ratio (%) of carbonized powder (a) and relative dielectric constant due to carbonized powder (a) of the electromagnetic wave absorbing plate (IIβ) containing 2 kinds of carbonized powders (a) and (b).

FIG. 18 is a graph showing the relationship between the weight ratio (%) of carbonized powder (b) and relative dielectric constant due to carbonized powder (b) of the electromagnetic wave absorbing plate (IIβ) containing 2 kinds of carbonized powders (a) and (b).

FIG. 19 is a graph showing the relationship between the weight ratio (%) of carbonized powder (c) and relative dielectric constant due to carbonized powder (c) of the electromagnetic wave absorbing plate (IIIβ) containing 2 kinds of carbonized powders (a) and (c).

FIG. 20 is a graph showing the relationship between the measured value and the calculated value of the relative dielectric constant (real part) of the electromagnetic wave absorbing plate (Iβ1) containing 3 kinds of carbonized powders (a), (b), and (c).

FIG. 21 is a graph showing the relationship between the measured value and the calculated value of the relative dielectric constant (imaginary part) of the electromagnetic wave absorbing plate (Iβ1) containing 3 kinds of carbonized powders (a), (b), (c).

### DETAILED DESCRIPTION OF THE PREFERRED EMBODIMENTS

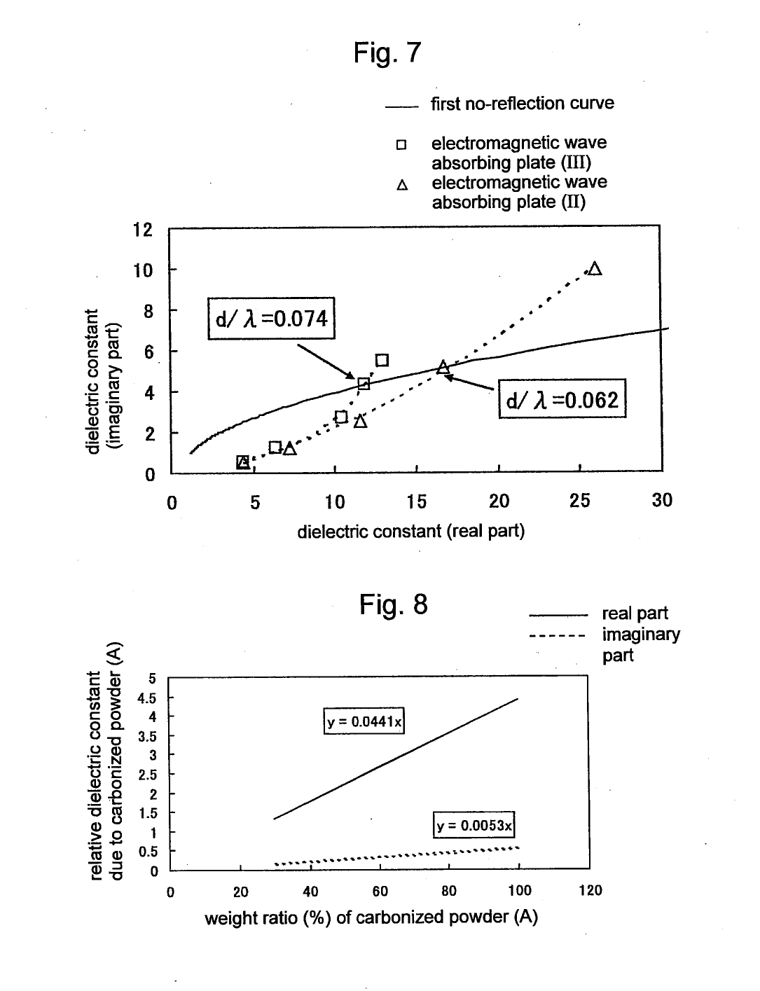

The present invention is based on the findings shown in the below-mentioned Experimental Example 1, FIG. 6, and FIG. 7; namely, when carbonized powders obtained by carbonizing a plant material at different carbonization temperatures are used, the characteristics (relative dielectric constant) of the obtained electromagnetic wave absorbing plate change vastly according to the carbonization temperatures.

Based on the finding, the present inventors have conducted intensive studies and found that the d/λ value in a non-reflective state can be adjusted to fall within a certain range rather than one point by using plural kinds of carbonized powders obtained by carbonizing a plant material at different carbonization temperatures and adjusting the weight ratio of such plural kinds of carbonized powders (see the below-mentioned Experimental Examples 2, 3 for the detail).

The present invention is based on the aforementioned findings, and one of the characteristics of the composition thereof is that it contains plural kinds of carbonized powders obtained by carbonizing a plant material at different carbonization temperatures.

The aforementioned carbonized powder preferably contains 3 kinds of carbonized powders obtained by carbonizing a plant material at the following carbonization temperatures (A)-(C):

(A) less than 850° C.,

(B) not less than 850° C. and less than 950° C.,

(C) not less than 950° C.

More preferable ranges of the carbonization temperatures of the aforementioned (A)-(C) are as follows:

(A) not less than 400° C. and not more than 800° C.,

(B) not less than 850° C. and not more than 930° C.,

(C) not less than 950° C. and not more than 3000° C.

The difference in the carbonization temperature between the aforementioned (A) and (B) is preferably not less than 100° C., more preferably not less than 200° C., and the difference in the carbonization temperature between the aforementioned (B) and (C) is preferably not less than 100° C., more preferably not less than 150° C.

In a more preferable embodiment of the present invention, the above-mentioned 3 kinds of temperature ranges (A)-(C) are further divided. That is, the aforementioned carbonized powder contains 3 or 4 kinds of carbonized powders selected from 4 kinds of carbonized powders obtained by carbonizing a plant material at the following carbonization temperatures (a)-(d):

(a) not less than 550° C. and less than 650° C.,

(b) not less than 650° C. and less than 800° C.,

(c) not less than 800° C. and less than 1000° C.,

(d) not less than 1000° C. and not more than 1200° C.

More preferable ranges of the carbonization temperatures of the aforementioned (A)-(d) are as follows:

(a) not less than 550° C. and not more than 630° C.,

(b) not less than 650° C. and not more than 730° C.,

(c) not less than 850° C. and less than 1000° C.,

(d) not less than 1100° C. and not more than 1200° C.

When 3 kinds are selected from the 4 kinds of carbonized powders the carbonization temperatures obtained by carbonizing at the aforementioned carbonization temperatures (a)-(d), combinations of {(a), (b), (c)}, {(a), (b), (d)}, {(a), (c), (d)}, and {(b), (c), (d)} are available, wherein the difference between the lowest carbonization temperature and the second lowest carbonization temperature is preferably not less than 50° C., more preferably not less than 70° C. The difference between the highest carbonization temperature and the second lowest(highest) carbonization temperature is, preferably not less than 100° C., more preferably not less than 150° C.

As the plant material, any plant material can be used as long as it can be carbonized, such as grass, wood, bamboo and the like. In the below-mentioned Experimental Examples, humus was use as a plant material. Since plant materials contain cellulose as a main component, a carbonized powder derived from a plant material other than humus is also considered to show similar characteristics as a carbonized powder derived from humus. Here, The “humus” means “pomace obtained by decomposing a plant-based protein of soybean and extracting amino acid from the decomposed product”.

The plant material used may be only one kind, or a combination of two or more kinds thereof. Even when one kind of a plant material is used, the characteristics of the obtained carbonized powder can be changed by merely changing the carbonization temperature. As a result, the d/λ value in a reflection state of an electromagnetic wave absorbing plate can be changed by merely obtaining plural kinds of carbonized powders from one kind of plant material by carbonizing at different carbonization temperatures, and adjusting the weight ratio of these carbonized powders. In other words, d/λ value can be adjusted by adjusting the weight ratio of these carbonized powders. As described above, since the object of the present invention can be achieved by merely changing the carbonization temperature without purchasing plural plant materials, one kind of plant material is preferably used.

From the aspect of recycling of resources, the plant material is preferably pomace of a plant after taking out components (fats and oils, protein, amino acid and the like); a scrap material or thinnings of wood, bamboo and the like; or the like. The plant material is more preferably humus. The humus can be obtained by, for example, defatting soybean, decomposing the obtained defatted soybean with an acid (e.g., hydrochloric acid), neutralizing same with a base (e.g., sodium hydroxide), extracting amino acid by squeezing, and washing the pomace with water and dehydrating same.

Plant materials can be carbonized using a known carbonizing apparatus. Examples of the carbonizing apparatus include muffle furnace manufactured by Isuzu Seisakusho Co., Ltd. and the like. The carbonization is preferably performed under an inert atmosphere (e.g., under a nitrogen atmosphere). The carbonization period is generally, 10 hours to 15 hours.

A carbonized powder can be obtained by milling and sieving, as necessary, carbide obtained by a carbonizer and the like. The milling can be performed using a known milling apparatus (e.g., ball mill, rod mill).

While the particle size of the carbonized powder to be used in the present invention is not particularly limited, and may be a particle size similar to that of a carbonized powder used for conventionally-known electromagnetic wave absorbers described in the above-mentioned JP-A-2002-368477, JP-A-2006-80502, WO 2010/03582, and JP-A-2010-153833. The volume average particle size of the carbonized powder to be used in the present invention is preferably 1 to 100 μm, more preferably 10 to 40 μm, by a measurement method according to JIS Z 8825-1 “particle size analysis-laser diffraction method”. This volume average particle size can be measured by Laser Diffraction Particle Size Distribution Analyzer “LA-950” manufactured by HORIBA, Ltd.

The total amount of the carbonized powder in the composition is preferably 50 to 200 parts by weight, more preferably 100 to 170 parts by weight, relative to 100 parts by weight of the resin. In the present specification, the ‘parts by weight of the carbonized powder’ relative to 100 parts by weight of the resin is sometimes indicated in terms of phr (parts per hundred parts by weight of resin).

The resin may be any of a thermoplastic resin and a thermosetting resin. The “resin” in the present invention is a concept also including a rubber. Only one kind of resin may be used, or two or more kinds thereof may be used in combination. In view of the intensity and the like of the obtained electromagnetic wave absorbing plate, the resin is preferably a thermosetting resin.

Examples of the thermosetting resin include phenolic resin, urea resin, melamine resin, epoxy resin, unsaturated polyester resin, alkyd resin, urethane resin and the like. Only one kind of thermosetting resin may be used, or two or more kinds thereof may be used in combination. Among these, phenolic resin is preferable. Phenolic resin may be a resol-type phenolic resin, a novolac-type phenolic resin or a mixture of these, preferably a novolac-type phenolic resin.

The composition of the present invention optionally contains a component other than the carbonized powder and the resin (hereinafter to be abbreviated as “other component”) as long as the effect of the invention is not impaired. Examples of other component include a dispersing agent to improve dispersibility of the carbonized powder, a curing agent for the thermosetting resin, a crosslinking agent for the rubber, a thickener and the like.

The composition of the present invention can be produced by mixing a carbonized powder and a resin, as well as other component as necessary. This step corresponds to the mixing step in the production method of the electromagnetic wave absorbing plate of the present invention.

The means for mixing is not particularly limited, and a known mixing apparatus can be used therefor. Examples of the known mixing apparatus include a mortar mixer, a planetary mixer and the like. The mixing time is not particularly limited, and can be appropriately set. For example, when a composition is prepared using a mortar mixer and the composition is formed into a sheet by a two-axle roller and the like, the mixing time in a mortar mixer is generally about 3 to 10 minutes, since dispersing of carbide is promoted even by kneading in a two-axle roller and the like. The composition may be cooled during mixing where necessary, since the temperature of the composition increases during mixing.

The electromagnetic wave absorbing plate of the present invention is obtained by forming the composition of the present invention. This step corresponds to the forming step in the production method of the electromagnetic wave absorbing plate of the present invention. A known forming apparatus may be used for the forming step.

The “plate” in the present invention also encompasses a sheet, a tape, a film, and the like.

Examples of the apparatus for forming the composition of the present invention into the electromagnetic wave absorbing plate of the present invention include a two-axle roller and the like. When a two-axle roller is used, it is preferable to run the composition of the present invention through a two-axle roller plural times, and knead the composition while drawing same in a plate shape. Such kneading promotes dispersing of carbide in the resin. Since temperature of the composition increases during such kneading, the composition may be cooled as necessary during the kneading.

When a thermosetting resin or a rubber is used as the resin, the obtained electromagnetic wave absorbing plate is cured after forming (curing step in the production method of the electromagnetic wave absorbing plate). While the method of curing may be heat curing, radiation curing and the like, convenient heat curing is preferable. The curing conditions (e.g., temperature and time of heat curing) can be appropriately determined depending on the kind of the thermosetting resin or rubber to be used, and the kind of the curing agent or crosslinking agent used as necessary.

The wavelength of the electromagnetic wave to be absorbed is within the range of microwave and millimeter wave band, preferably 100 μm to 1 m, more preferably 1.5 mm to 0.06 m. The thickness of the obtained electromagnetic wave absorbing plate is determined according to the wavelength of the electromagnetic wave to be absorbed. For example, the thickness of an electromagnetic wave absorbing plate can be 6.2 to 7.4 μm relative to wavelength 100 μm of the electromagnetic wave. In addition, the thickness of an electromagnetic wave absorbing plate can be 62 to 74 mm relative to wavelength 1 m of the electromagnetic wave.

The production method of the electromagnetic wave absorbing plate of the present invention includes the aforementioned mixing step and forming step, as well as a curing step where necessary.

The production method of the electromagnetic wave absorbing plate of the present invention is characterized in that, in the aforementioned mixing step,

3 kinds of carbonized powders obtained by carbonizing a plant material at the carbonization temperatures of the aforementioned (A)-(C) are used, and

each of the aforementioned 3 kinds of carbonized powders has a weight ratio adjusted according to a d/λ value in a non-reflective state, such that the electromagnetic wave absorbing plate is in a non-reflective state.

In addition, a more preferable embodiment the production method of the electromagnetic wave absorbing plate of the present invention is characterized in that, in the aforementioned mixing step,

3 or 4 kinds of carbonized powders selected from the aforementioned 4 kinds of carbonized powders obtained by carbonizing a plant material at the carbonization temperatures of the following (a)-(d) are used, and

each of the 3 or 4 kinds of carbonized powders selected from the aforementioned 4 kinds has a weight ratio adjusted according to a d/λ value in a non-reflective state, such that the electromagnetic wave absorbing plate is in a non-reflective state.

Here, the non-reflective state of the electromagnetic wave absorbing plate is achieved at an intersection point of a curve of a graph showing the relationship between the real part and the imaginary part of the relative dielectric constant, and the first no-reflection curve. The relative dielectric constant of the electromagnetic wave absorbing plate can be measured as described in the below-mentioned Experimental Examples, and a graph showing the relationship between the real part and the imaginary part of a relative dielectric constant can be formed by plotting the values of the real part and the imaginary part.

In general, the first no-reflection curve of an electromagnetic wave absorber using a dielectric absorbing material can be expressed by the formula 1.

$$\begin{matrix}1 = \frac{1}{\sqrt{{\dot{ɛ}}_{r}}} tan h ( j \frac{2 π d}{λ} \sqrt{{\dot{ɛ}}_{r}} ) & 1 \\ {\dot{ɛ}}_{r} = {ɛ}_{r}^{′} + j {ɛ}_{r}^{″} & 2\end{matrix}$$

wherein ∈ᵣ is a relative dielectric constant, d is the thickness of the absorbing plate, λ is the wavelength of the electromagnetic wave.

∈ᵣ is divided into ∈′ᵣ (real part) and ∈″ᵣ (imaginary part), as shown in the formula 2.

In the formula 1, the first no-reflection curve can be formed by changing d/λ, which is the thickness of the absorbing plate normalized by wavelength λ (i.e., value obtained by dividing thickness d of absorbing plate by wavelength λ).

The first no-reflection curve is explained in, for example, Osamu Hashimoto, “Denpakyushuban no hanashi (The story of radio wave absorbing plate)” Nikkan Kogyo Shimbun Ltd., page 45, 3.1.2, which is shown as the graph in FIG. 1.

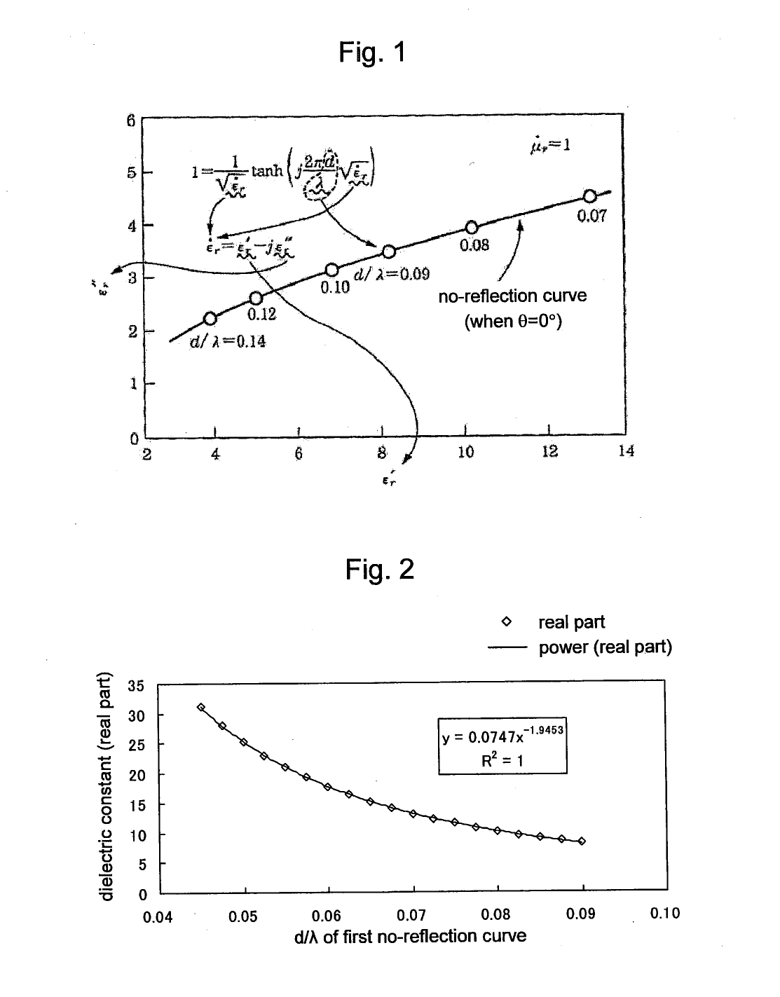

From the above-mentioned formula 1, a graph showing the relationship between d/λ of the first no-reflection curve and relative dielectric constant (real part) ∈′ᵣ is as shown in FIG. 2, and the formula 3 can be obtained from the approximation thereof.

$${ɛ}_{r}^{′} = 0.0747 {( \frac{d}{λ} )}^{- 1.9453} \qquad 3$$

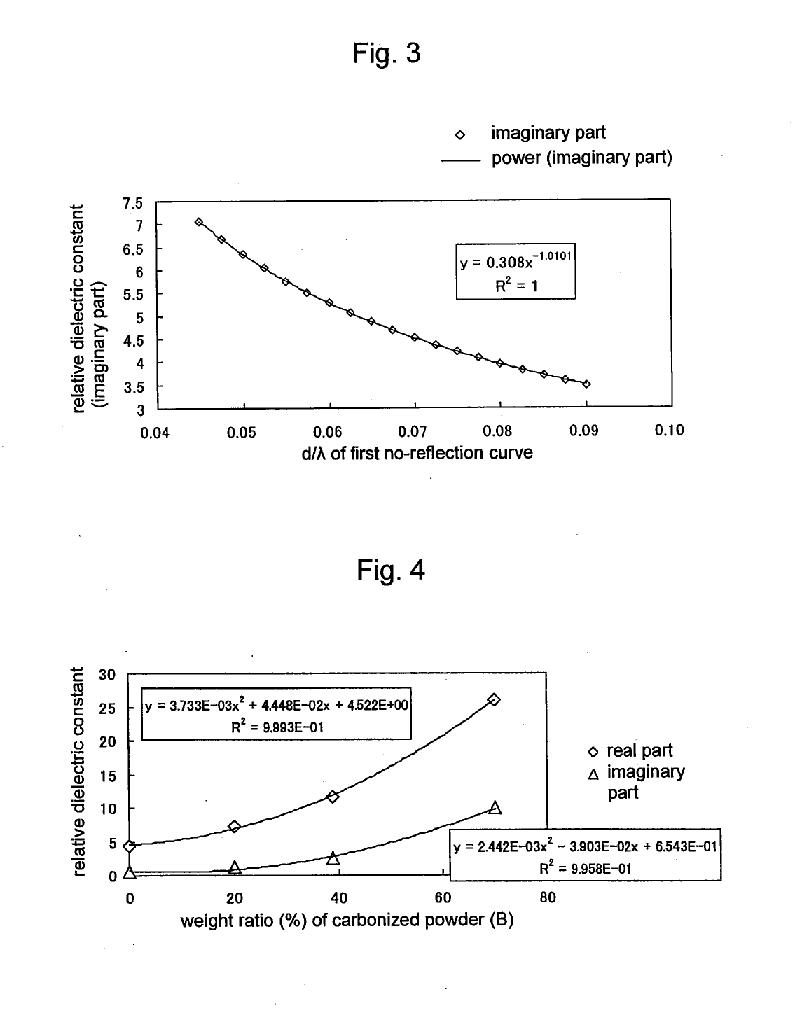

Similarly, from the above-mentioned formula 1, a graph showing the relationship between d/λ of the first no-reflection curve and relative dielectric constant (imaginary part) ∈″ᵣ is as shown in FIG. 3, and the formula 4 can be obtained from the approximation thereof.

$${ɛ}_{r}^{″} = 0.308 {( \frac{d}{λ} )}^{- 1.0101} \qquad 4$$

In a conventionally-known electromagnetic wave absorbing plate, only one d/λ achieving the non-reflective state of the electromagnetic wave absorbing plate is present at an intersection point of a curve of a graph showing the relationship between the real part and the imaginary part of the relative dielectric constant, and the first no-reflection curve.

In the present invention, the d/λ value at an intersection point of a curve of a graph showing the relationship between the real part and the imaginary part of the relative dielectric constant, and the first no-reflection curve (i.e., non-reflective state) can be determined by the following method and can also be adjusted.

Embodiment 1: adjusting method of d/λ when 3 kinds of carbonized powders obtained by carbonizing a plant material at the carbonization temperatures of the aforementioned (A)-(C) are used.

First, plural kinds of samples of an electromagnetic wave absorbing plate containing carbonized powders (A) and (B) are produced by changing the weight ratio of the carbonized powders (A), (B) variously, and respective relative dielectric constants are measured (e.g., below-mentioned Experimental Example, Table 2).

A graph (FIG. 4), showing the relationship between the weight ratio of carbonized powder (B) and the relative dielectric constant of the electromagnetic wave absorbing plate (II) containing 2 kinds of carbonized powders (A) and (B), is formed from the measurement results (Table 2). When carbonized powders (A) and (B) are contained, the weight ratio of the carbonized powder (B) is a ratio of weight (B) to the sum of the weight of (A) and (B), i.e., [B/(A+B)]×100(%). The same applies to other combinations such as (A)+(B)+(C) and the like.

In FIG. 4, “E-02”, “E-01” and “E+00” means “10⁻²”, “10⁻¹” and “10⁰”, respectively. The same applies to other Figures.

From the two curves (curve of real part, curve of imaginary part) in the graph of FIG. 4, an approximation formula of the curve showing the relationship between the weight ratio of carbonized powder (B) and real part of the relative dielectric constant (the following formula 5), and an approximation formula of the curve showing the relationship between the weight ratio of carbonized powder (B) and imaginary part of the relative dielectric constant (the following formula 6) are determined.

In the formula 5 and the formula 6, R_{B} is weight ratio (%) of carbonized powder (B), and ∈′_{rAB} and ∈″_{rAB} are the real part and the imaginary part of the relative dielectric constant of electromagnetic wave absorbing plate (II).

∈′_{rAB}=3.733×10⁻³R_{B}²+4.448×10⁻²R_{B}+4.522 5

∈″_{rAB}=2.442×10⁻³R_{B}²−3.903×10⁻²R_{B}+0.6543 6

In this case, d/λ and weight ratio R_{B} at the intersection point of the curve of a graph showing the relationship between the real part and the imaginary part of the relative dielectric constant, and the first no-reflection curve satisfy the following relationships.

The relative dielectric constant (real part) ∈′ᵣ at d/λ of the first no-reflection curve of the formula 3 and relative dielectric constant (real part) ∈′_{rAB} at weight ratio R_{B} of the electromagnetic wave absorbing plate of the formula 5 are the same, and

the relative dielectric constant (imaginary part) ∈″ᵣ at d/λ of the first no-reflection curve of the formula 4 and relative dielectric constant (imaginary part) ∈″_{rAB} at weight ratio R_{B} of the electromagnetic wave absorbing plate of the formula 6 are the same.

This relationship is expressed by the formula 7 and the formula 8.

$$\begin{matrix}0.0747 {( \frac{d}{λ} )}^{- 1.9453} = 3.733 \times {10}^{- 3} {R}_{B}^{2} + 4.448 \times {10}^{- 2} {R}_{B}^{*} + 4.522 & 7 \\ 0.308 {( \frac{d}{λ} )}^{- 1.0101} = 2.442 \times {10}^{- 3} {R}_{B}^{2} - 3.903 \times {10}^{- 2} {R}_{B} + 0.6543 & 8\end{matrix}$$

The results shown by the formula 9 and the formula 10 are obtained by solving the simultaneous equations of the formula 7 and the formula 8.

$$\begin{matrix}( \frac{d}{λ} ) = 0.062 & 9 \\ {R}_{B} = 52 & 10\end{matrix}$$

That is, in the example of Table 2, a curve of a graph showing the relationship between the real part and the imaginary part of the relative dielectric constant of the electromagnetic wave absorbing plate (II) containing 2 kinds of carbonized powders (A) and (B), and the first no-reflection curve intersect at R_{B}=about 52(%), and d/λ of the intersection point is 0.062.

Then, plural kinds of samples of an electromagnetic wave absorbing plate containing carbonized powders (A) and (C) are produced by changing the weight ratio of the carbonized powders (A), (C) variously, and respective relative dielectric constants are measured (e.g., below-mentioned Experimental Example, Table 3).

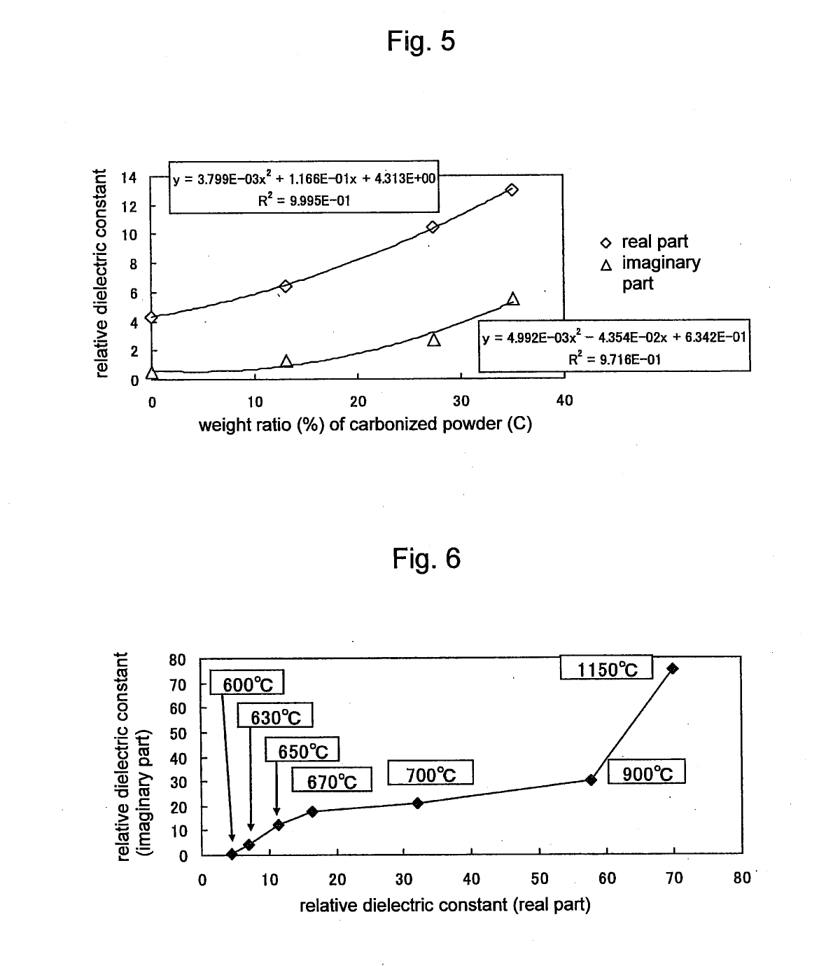

In the same manner as above, a graph showing the relationship between the weight ratio of carbonized powder (C) and the relative dielectric constant of the electromagnetic wave absorbing plate (III) containing 2 kinds of carbonized powders (A) and (C) is formed from Table 3 (FIG. 5). Then, from the two curves (curve of real part, curve of imaginary part) in the graph of FIG. 5, an approximation formula of the curve showing the relationship between the weight ratio of carbonized powder (C) and real part of the relative dielectric constant (the following formula 11), and an approximation formula of the curve showing the relationship between the weight ratio of carbonized powder (C) and imaginary part of the relative dielectric constant (the following formula 12) are determined.

In the formula 11 and the formula 12, R_{C} is weight ratio (%) of carbonized powder (C), and ∈′_{rAC} and ∈″_{rAC} are the real part and the imaginary part of the relative dielectric constant of electromagnetic wave absorbing plate (III).

∈′_{rAC}=3.799×10⁻³R_{C}²+4.165×10⁻¹R_{C}+4.313 11

∈″_{rAC}=4.992×10⁻³R_{C}²−4.354×10⁻²R_{C}+0.6342 12

In this case, d/λ and weight ratio R_{c} at the intersection point of the curve of a graph showing the relationship between the real part and the imaginary part of the relative dielectric constant, and the first no-reflection curve satisfy the following relationships.

The relative dielectric constant (real part) ∈′ᵣ at d/λ of the first no-reflection curve of the formula 3 and relative dielectric constant (real part) ∈′_{rAC} at weight ratio R_{C} of the electromagnetic wave absorbing plate of the formula 11 are the same, and

the relative dielectric constant (imaginary part) ∈″ᵣ at d/λ of the first no-reflection curve of the formula 4 and relative dielectric constant (imaginary part) ∈″_{rAC} at weight ratio R_{C} of the electromagnetic wave absorbing plate of the formula 12 are the same.

This relationship is expressed by the formula 13 and the formula 14.

$$\begin{matrix}0.0747 {( \frac{d}{λ} )}^{- 1.9453} = 3.799 \times {10}^{- 3} {R}_{C}^{2} + 4.165 \times {10}^{- 1} {R}_{C} + 4.313 & 13 \\ 0.308 {( \frac{d}{λ} )}^{- 1.0101} = 4.992 \times {10}^{- 3} {R}_{C}^{2} - 4.354 \times {10}^{- 2} {R}_{C} + 0.6342 & 14\end{matrix}$$

The results shown by the formula 15 and the formula 16 are obtained by solving the simultaneous equations of the formula 13 and the formula 14.

$$\begin{matrix}( \frac{d}{λ} ) = 0.074 & 15 \\ {R}_{C} = 32 & 16\end{matrix}$$

That is, in the example of Table 3, a curve of a graph showing the relationship between the real part and the imaginary part of the relative dielectric constant of the electromagnetic wave absorbing plate (III) containing 2 kinds of carbonized powders (A) and (C), and the first no-reflection curve intersect at R_{C}=about 32(%), and d/λ of the intersection point is 0.074.

As mentioned above, the electromagnetic wave absorbing plate (II) containing 2 kinds of carbonized powders (A), (B) and the electromagnetic wave absorbing plate (III) containing 2 kinds of carbonized powders (A), (C) have d/λ values in a non-reflective state, which are different from each other (see the below-mentioned Experimental Example 2 and FIG. 7).

According to the finding of the present invention, d/λ value C_{I} can be adjusted to fall between C_{II} and C_{III}, wherein the electromagnetic wave absorbing plate (I) containing 3 kinds of carbonized powders (A)-(C) is formed, and the d/λ value in a non-reflective state of the electromagnetic wave absorbing plate (I), the above-mentioned electromagnetic wave absorbing plates (II) and (III) is C_{I}-C_{III}, respectively, by adjusting the weight ratio of each of the carbonized powders (A)-(C).

In other words, as shown in FIG. 7, the intersection points of respective curves in the graphs showing the relationship between the real part and the imaginary part of the relative dielectric constants of the electromagnetic wave absorbing plates (II) and (III), and the first no-reflection curve are positioned far from each other, and the intersection point of the curve of the graph showing the relationship between the real part and the imaginary part of the relative dielectric constant of the electromagnetic wave absorbing plate (I), and the first no-reflection curve can be determined between these two intersection points.

For example, when C_{I} is desired to be closer to C_{II}, the weight ratio of the carbonized powder (B) in the electromagnetic wave absorbing plate (I) only needs to be increased, and when C_{I} is desired to be closer to C_{III}, the weight ratio of the carbonized powder (C) in the electromagnetic wave absorbing plate (I) only needs to be increased.

As mentioned above, when 3 kinds of carbonized powders obtained by carbonizing a plant material at the carbonization temperatures of the aforementioned (A)-(C) are used, the d/λ value in a non-reflective state of the electromagnetic wave absorbing plate can be adjusted by adjusting each weight ratio of the carbonized powders (A)-(C).

Therefore, for example, when the wavelength λ of the aforementioned electromagnetic wave is fixed at a given value, the thickness d of the electromagnetic wave absorbing plate to achieve a non-reflective state relative to the aforementioned wavelength λ can be changed by changing each weight ratio of the carbonized powders (A)-(C). Conversely, when the thickness d of an electromagnetic wave absorbing plate is fixed at a given value, the wavelength λ of the aforementioned electromagnetic wave which achieves a non-reflective state relative to the aforementioned thickness d can be changed by changing each weight ratio of the carbonized powders (A)-(C).

### Embodiment 2

adjusting method of d/λ when 3 or 4 kinds of carbonized powders selected from the aforementioned 4 kinds of carbonized powders obtained by carbonizing a plant material at the carbonization temperatures of the following (a)-(d) are used.

In the same manner as in the above-mentioned use of 3 kinds of carbonized powders (A)-(C), plural kinds of samples of each of an electromagnetic wave absorbing plate [containing (a), (b)] containing various weight ratios of [carbonized powders (a), (b)], an electromagnetic wave absorbing plate [containing (a), (c)] containing various weight ratios of [carbonized powders (a), (c)] and an electromagnetic wave absorbing plate [containing (a), (d)] containing various weight ratios of [carbonized powders (a), (d)] are produced, and each relative dielectric constant is measured (e.g., Table 5, Table 6, Table 7 of below-mentioned Experimental Example 3, and Table 3 of Experimental Example 2).

While Table 3 of Experimental Example 2 relates to the electromagnetic wave absorbing plate with variously changed weight ratio of [carbonized powder (A: 600° C.), (C: 1150° C.)], Table 3 also relates to the electromagnetic wave absorbing plate with variously changed weight ratio of [carbonized powder (a: 600° C.), (d: 1150° C.)] in Experimental Example 3.

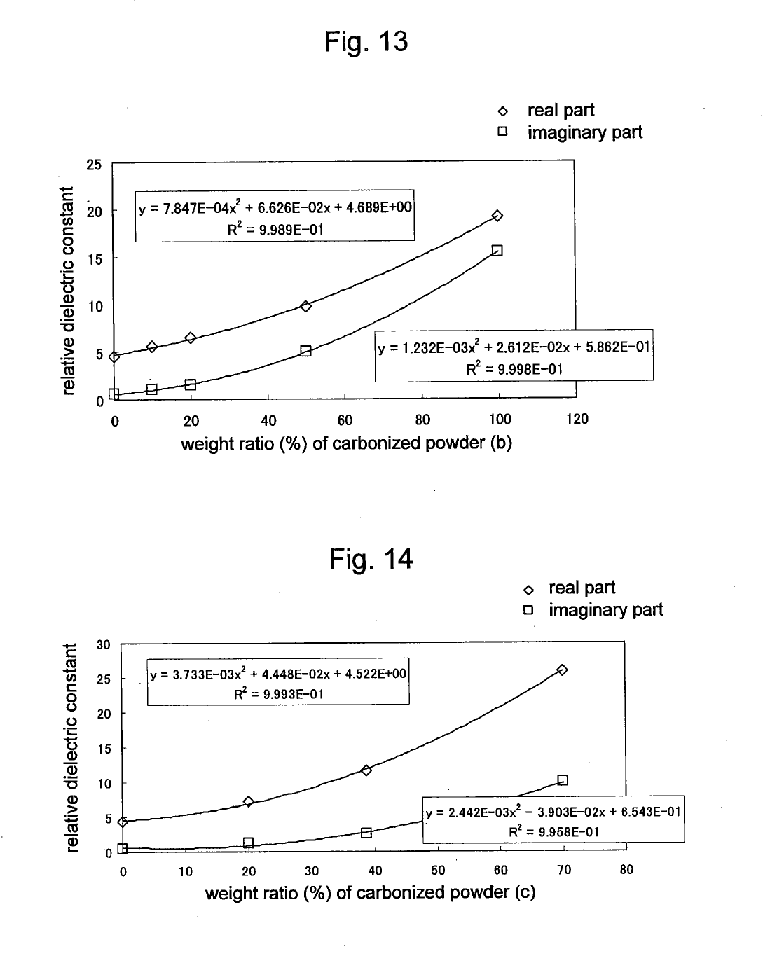

First, a graph showing the relationship between the weight ratio of carbonized powder (b) and the relative dielectric constant of the electromagnetic wave absorbing plate (IIβ) containing 2 kinds of carbonized powders (a) and (b) is formed from Table 5 in the measurement results (FIG. 13).

In the same manner as in the above-mentioned embodiment 1, from the two curves (curve of real part, curve of imaginary part) in the graph of FIG. 13, an approximation formula of the curve showing the relationship between the weight ratio of carbonized powder (b) and real part of the relative dielectric constant (the following formula 5β), and an approximation formula of the curve showing the relationship between the weight ratio of carbonized powder (b) and imaginary part of the relative dielectric constant (the following formula 6β) are determined.

In the formula 5β and the formula 6β, R_{B} is weight ratio (%) of carbonized powder (b), and ∈′_{rab} and ∈″_{rab} are the real part and the imaginary part of the relative dielectric constant of electromagnetic wave absorbing plate (IIβ).

∈′_{rab}=2.585×10⁻⁴R_{b}²+9.253×10⁻²R_{b}+4.552 5 5β

∈″_{rab}=1.682×10⁻³R_{b}²+3.698×10⁻³R_{b}+0.7035 6β

In this case, d/λ and weight ratio R_{b} at the intersection point of the curve of a graph showing the relationship between the real part and the imaginary part of the relative dielectric constant, and the first no-reflection curve satisfy the following relationships.

The relative dielectric constant (real part) ∈′ᵣ at d/λ of the first no-reflection curve of the formula 3 and relative dielectric constant (real part) ∈′_{rab} at weight ratio R_{B} of the electromagnetic wave absorbing plate of the formula 5β are the same, and

the relative dielectric constant (imaginary part) ∈″ᵣ at d/λ of the first no-reflection curve of the formula 4 and relative dielectric constant (imaginary part) ∈″_{rab} at weight ratio R_{b} of the electromagnetic wave absorbing plate of the formula 6β are the same.

This relationship is expressed by the formula 7β and the formula 8β.

$$\begin{matrix}0.0747 {( \frac{d}{λ} )}^{- 1.9453} = 2.585 \times {10}^{- 4} {R}_{b}^{2} + 9.253 \times {10}^{- 2} {R}_{b} + 4.552 & 7 β \\ 0.308 {( \frac{d}{λ} )}^{- 1.0101} = 1.682 \times {10}^{- 3} {R}_{b}^{2} + 3.698 \times {10}^{- 3} {R}_{b} + 0.7035 & 8 β\end{matrix}$$

The results shown by the formula 9β and the formula 10β are obtained by solving the simultaneous equations of the formula 7β and the formula 8β.

$$\begin{matrix}( \frac{d}{λ} ) = 0.087 & 9 β \\ {R}_{b} = 40.4 & 10 β\end{matrix}$$

That is, in the example of Table 5, a curve of a graph showing the relationship between the real part and the imaginary part of the relative dielectric constant of the electromagnetic wave absorbing plate (IIβ) containing 2 kinds of carbonized powders (a) and (b), and the first no-reflection curve intersect at R_{B}=about 40(%), and d/λ of the intersection point is 0.087.

In the same manner as above, a graph (FIG. 14), showing the relationship between the weight ratio of carbonized powder (c) and the relative dielectric constant of the electromagnetic wave absorbing plate (IIIβ) containing 2 kinds of carbonized powders (a) and (c), is formed from Table 6. Then, from the two curves (curve of real part, curve of imaginary part) in the graph of FIG. 14, an approximation formula (the following formula 11β) of the curve showing the relationship between the weight ratio of carbonized powder (c) and real part of the relative dielectric constant, and an approximation formula (the following formula 12β) of the curve showing the relationship between the weight ratio of carbonized powder (c) and imaginary part of the relative dielectric constant are determined.

In the formula 11β and the formula 12β, R_{C} is weight ratio (%) of carbonized powder (c), and ∈′_{rac} and ∈″_{rac} are the real part and the imaginary part of the relative dielectric constant of electromagnetic wave absorbing plate (IIIβ).

∈′_{rac}=3.733×10⁻³R_{c}²+4.448×10⁻²R_{c}+4.522 1β

∈″_{rac}=2.442×10⁻³R_{c}²−3.903×10⁻²R_{c}+0.6543 12β

In this case, d/λ value and weight ratio R_{c} at the intersection point of the curve of a graph showing the relationship between the real part and the imaginary part of the relative dielectric constant, and the first no-reflection curve satisfy the following relationships.

The relative dielectric constant (real part) ∈′ᵣ at d/λ of the first no-reflection curve of the formula 3 and relative dielectric constant (real part) ∈′_{rac} at weight ratio R_{c} of the electromagnetic wave absorbing plate of the formula 11β are the same, and

the relative dielectric constant (imaginary part) ∈″ᵣ at d/λ of the first no-reflection curve of the formula 4 and relative dielectric constant (imaginary part) ∈″_{rac} at weight ratio R_{C} of the electromagnetic wave absorbing plate of the formula 12β are the same.

This relationship is expressed by the formula 13β and the formula 14β.

$$\begin{matrix}0.0747 {( \frac{d}{λ} )}^{- 1.9453} = 3.733 \times {10}^{- 3} {R}_{c}^{2} + 4.448 \times {10}^{- 2} {R}_{c} + 4.552 & 13 β \\ 0.308 {( \frac{d}{λ} )}^{- 1.0101} = 2.442 \times {10}^{- 3} {R}_{c}^{2} - 3.903 \times {10}^{- 2} {R}_{c} + 0.6543 & 14 β\end{matrix}$$

The results shown by the formula 15β and the formula 16β are obtained by solving the simultaneous equations of the formula 13β and the formula 14β.

$$\begin{matrix}( \frac{d}{λ} ) = 0.062 & 15 β \\ {R}_{c} = 52 & 16 β\end{matrix}$$

That is, in the example of Table 6, a curve of a graph showing the relationship between the real part and the imaginary part of the relative dielectric constant of the electromagnetic wave absorbing plate (IIIβ) containing 2 kinds of carbonized powders (a) and (c), and the first no-reflection curve intersect at R_{C}=about 52(%), and d/λ of the intersection point is 0.062.

In the same manner as above, a graph showing the relationship between the weight ratio of carbonized powder (d) and the relative dielectric constant of the electromagnetic wave absorbing plate (nip) containing 2 kinds of carbonized powders (a) and (d) is formed from Table 3 (same graph as FIG. 5). Then, from the two curves (curve of real part, curve of imaginary part) in the graph, an approximation formula of the curve showing the relationship between the weight ratio of carbonized powder (d) and real part of the relative dielectric constant (the following formula 17β1), and an approximation formula of the curve showing the relationship between the weight ratio of carbonized powder (d) and imaginary part of the relative dielectric constant (the following formula 18β1) are determined.

In the formula 17β1 and the formula 18β1, R_{d} is weight ratio (%) of carbonized powder (d), and ∈′_{rad} and ∈″_{rad} are the real part and the imaginary part of the relative dielectric constant of electromagnetic wave absorbing plate (IVβ).

∈′_{rad}=3.799×10⁻³R_{d}²+4.165×10⁻¹R_{d}+4.313 17β1

∈″_{rad}=4.992×10⁻³R_{d}²4.354×10⁻²R_{d}+0.6342 18β1

In this case, the relationship between d/λ value and weight ratio R_{C} at the intersection point of the curve of a graph showing the relationship between the real part and the imaginary part of the relative dielectric constant, and the first no-reflection curve satisfies the following relationships.

The relative dielectric constant (real part) ∈′ᵣ at d/λ of the first no-reflection curve of the formula 3 and relative dielectric constant (real part) ∈′_{rad} at weight ratio R_{d} of the electromagnetic wave absorbing plate of the formula 17β1 are the same, and

the relative dielectric constant (imaginary part) ∈″ᵣ at d/λ of the first no-reflection curve of the formula 4 and relative dielectric constant (imaginary part) ∈″_{rad} at weight ratio R_{d} of the electromagnetic wave absorbing plate of the formula 18β1 are the same.

This relationship is expressed by the formula 19β1 and the formula 20β1.

$$\begin{matrix}0.0747 {( \frac{d}{λ} )}^{- 1.9453} = 3.799 \times {10}^{- 3} {R}_{d}^{2} + 4.165 \times {10}^{- 1} {R}_{d} + 4.313 & 19 β1 \\ 0.308 {( \frac{d}{λ} )}^{- 1.0101} = 4.992 \times {10}^{- 3} {R}_{d}^{2} - 4.354 \times {10}^{- 2} {R}_{d} + 0.6342 & 20 β1\end{matrix}$$

The results shown by the formula 21β1 and the formula 22β1 are obtained by solving the simultaneous equations of the formula 19β1 and the formula 20β1.

$$\begin{matrix}( \frac{d}{λ} ) = 0.074 & 21 β1 \\ {R}_{d} = 32 & 22 β1\end{matrix}$$

That is, in the same manner as in the electromagnetic wave absorbing plate (III) containing 2 kinds carbonized powder (A) and (C), a curve of a graph showing the relationship between the real part and the imaginary part of the relative dielectric constant of the electromagnetic wave absorbing plate (IVβ) containing 2 kinds of carbonized powders (a) and (d), and the first no-reflection curve intersect at R_{d}=about 32(%), and d/λ of the intersection point is 0.074 as shown in the graph of FIG. 16.

The electromagnetic wave absorbing plate (IIβ) containing 2 kinds of carbonized powders (a), (b), electromagnetic wave absorbing plate (IIIβ) containing 2 kinds of carbonized powders (a), (c), and the electromagnetic wave absorbing plate (IVβ) containing 2 kinds of carbonized powders (a), (d) have d/λ values in a non-reflective state, which are different from each other (see the below-mentioned Experimental Example 3 and FIG. 16).

In the same manner as in the above-mentioned embodiment 1, d/λ value C_{Iβ} can be adjusted to fall between C_{IIβ}-C_{IIIβ}, wherein the electromagnetic wave absorbing plate (1β1) containing 3 kinds of carbonized powders (a), (b), (c) is formed, and the d/λ value in a non-reflective state of the electromagnetic wave absorbing plate (Iβ1), the above-mentioned electromagnetic wave absorbing plates (IIβ) and (IIIβ) is C_{IIβ}-C_{IIIβ}, respectively, by adjusting the weight ratio of each of the carbonized powders (a), (b), (c).

In other words, as shown in FIG. 16, the intersection points of respective curves in the graphs showing the relationship between the real part and the imaginary part of the relative dielectric constants of the electromagnetic wave absorbing plates (IIβ) and (IIIβ), and the first no-reflection curve are positioned far from each other, and the intersection point of the curve of the graph showing the relationship between the real part and the imaginary part of the relative dielectric constant of the electromagnetic wave absorbing plate (Iβ1), and the first no-reflection curve can be determined between these two intersection points.

For example, when C_{Iβ} is desired to be closer to C_{IIβ}, the weight ratio of the carbonized powder (b) in the electromagnetic wave absorbing plate (Iβ1) only needs to be increased, and conversely, when C_{Iβ} is desired to be closer to C_{IIIβ}, the weight ratio of the carbonized powder (c) in the electromagnetic wave absorbing plate (Iβ1) only needs to be increased.

As mentioned above, when 3 kinds (e.g., (a), (b), (c)) of carbonized powders selected from 4 kinds of carbonized powders obtained by carbonizing a plant material at the carbonization temperatures of the aforementioned (a)-(d) are used, the d/λ value in a non-reflective state of the electromagnetic wave absorbing plate can be adjusted by adjusting each weight ratio of the carbonized powders (a), (b), (c).

In addition, in the same manner as in the use of 3 kinds of carbonized powders, even when all 4 kinds of carbonized powders are used, the d/λ value in a non-reflective state of the electromagnetic wave absorbing plate can be adjusted by adjusting each weight ratio of the carbonized powders (a), (b), (c), and (d).

For example, in the graph shown in FIG. 16, the d/λ value in a non-reflective state of the electromagnetic wave absorbing plate can be adjusted from 0.087 to 0.062 by adjusting each weight ratio of the carbonized powders (a)-(d).

Other features of the invention will become apparent in the course of the following descriptions of exemplary embodiments which are given for illustration of the invention and are not intended to be limiting thereof.

### EXAMPLES

### Experimental Example 1

### (1) Production of Carbonized Powder

Humus was carbonized in a muffle furnace (“EPDS-7.2P” manufactured by Isuzu Seisakusho Co., Ltd.) under a nitrogen atmosphere at 600° C., 630° C., 650° C., 670° C., 700° C., 850° C., 900° C., 1050° C. or 1150° C. for 12 hours to produce 9 kinds of carbonized powders.

The volume average particle size of the obtained 9 kinds of carbonized powders was about 25 μm (20-28 μm) for all of them (measurement device: “LA-950” manufactured by HORIBA Ltd., dispersing medium: H₂O (refractive index 1.33), ultrasonic dispersion: 3 minutes).

### (2) Production of Composition

The 9 kinds of carbonized powders obtained above were respectively mixed with a novolac-type phenolic resin to form 9 kinds of compositions.

In mixing, each carbonized powder (130 parts by weight) and a novolac-type phenolic resin (“PHENOLITE J-325” manufactured by DIC, 100 parts by weight) were mixed in a mortar mixer (“SS-C-413” manufactured by Shinohara Seisakusho) for 5 min. They were mixed at 140 rpm for the first 2 minutes and at 280 rpm for 3 minutes and thereafter.

### (3) Production of Electromagnetic Wave Absorbing Plate

The 9 kinds of compositions obtained above were each kneaded by passing them total 30 times through a two-axle roller (“R2-2” manufactured by Kodaira Seisakusho, distance between rollers: 1.0 mm) rotating at 15 rpm to produce 9 kinds of sheets (electromagnetic wave absorbing plates) wherein each carbonized powder was singly dispersed in the novolac-type phenolic resin. Since the composition produce heat during kneading, cooling water was flown through the rolls to knead the composition with cooling.

The 9 kinds of sheets obtained above were cut into the size of length 100 mm×width 100 mm with a cutter. Each sheet after cutting was cured by heating in an oven (“DOV-600P” manufactured by AS ONE) under an air atmosphere to produce 9 kinds of electromagnetic wave absorbing plates.

The heating conditions were as described below:

First, the temperature was raised from ambient temperature to 80° C. over 1 hour, and then kept at 80° C. for 2 hours. Then the temperature was raised from 80° C. to 135° C. over 2 hours and then kept at 135° C. for 3 hours. Then the temperature was raised from 135° C. to 180° C. over 3 hours and then kept at 180° C. for 14 hours. Thereafter, the oven was closed, the power source thereof was turned off, and the plate was allowed to slowly cool to ordinary temperature. The thickness of the each obtained electromagnetic wave absorbing plate was 1.4 mm.

### (4) Measurement of Relative Dielectric Constant of Electromagnetic Wave Absorbing Plate

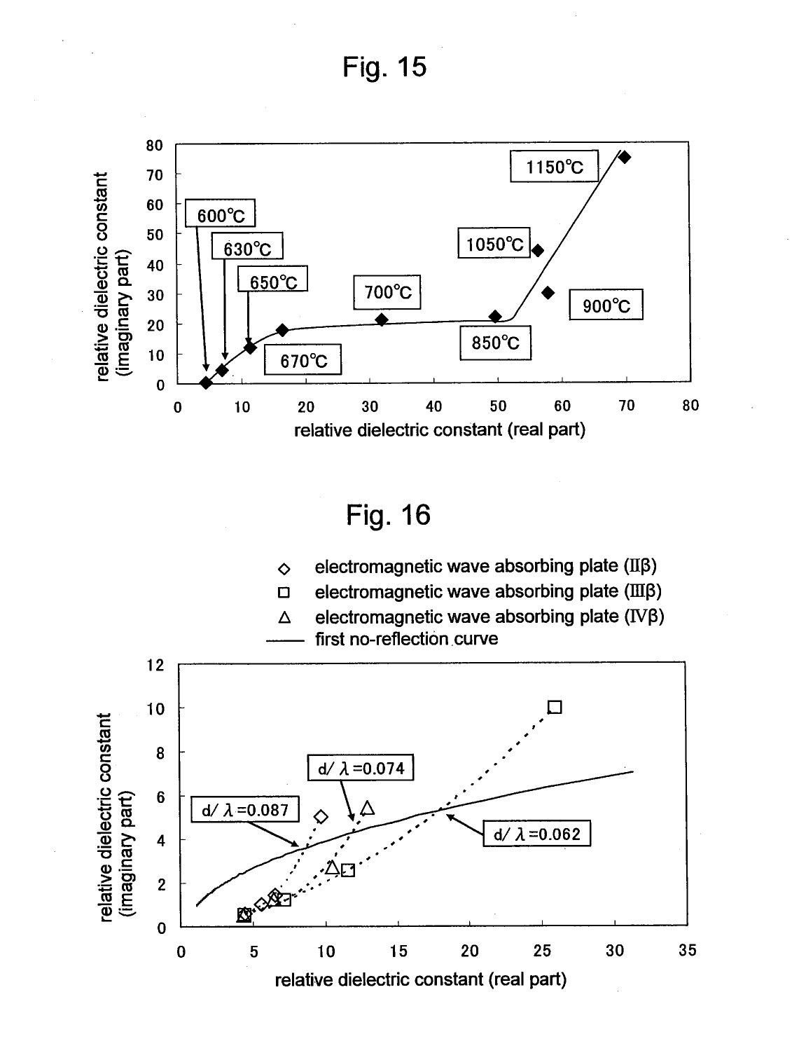

Using a vector network analyzer (“E8364A 45 MHz-50 GHz” manufactured by Agilent Technologies) according to the lens method at 18.0-26.5 GHz, the relative dielectric constant of the 9 kinds of electromagnetic wave absorbing plates (thickness 1.4 mm, carbonized powder content: 130 phr) obtained above was each measured. The results are shown in Table 1 and FIG. 15.

TABLE 1

| | |
|---|---|
| | relative dielectric |
| carbonized | constant |

| | carbonization | powder | real | imaginary |
|---|---|---|---|---|
| | temperature | content | part | part |
| No. 1 | 600° C. | 130 phr | 4.5 | 0.6 |
| No. 2 | 630° C. | 130 phr | 7.0 | 4.5 |
| No. 3 | 650° C. | 130 phr | 11.4 | 12.1 |
| No. 4 | 670° C. | 130 phr | 16.4 | 17.9 |
| No. 5 | 700° C. | 130 phr | 32.0 | 21.0 |
| No. 6 | 850° C. | 130 phr | 49.6 | 21.8 |
| No. 7 | 900° C. | 130 phr | 57.8 | 29.8 |
| No. 8 | 1050° C. | 130 phr | 56.4 | 44.0 |
| No. 9 | 1150° C. | 130 phr | 70.0 | 75.0 |

As shown in Table 1 and FIG. 15, the electromagnetic wave absorbing plate containing a carbonized powder having a carbonization temperature of 600° C. showed a small real part and a small imaginary part of the relative dielectric constant.

The electromagnetic wave absorbing plate containing a carbonized powder having a carbonization temperature of 670° C. showed somewhat larger real part and somewhat larger imaginary part of the relative dielectric constant.

The electromagnetic wave absorbing plate containing carbonized powder having a carbonization temperature of 900° C. showed increased real part as compared to the carbonized powder having a carbonization temperature of 670° C., though the imaginary part of the relative dielectric constant did not change much.

The electromagnetic wave absorbing plate containing carbonized powder having a carbonization temperature of 1150° C. showed markedly increased imaginary part as compared to the carbonized powder having a carbonization temperature of 900° C. Thus, it was found that the relative dielectric constant of the obtained electromagnetic wave absorbing plate varies markedly when carbonized powders with different carbonization temperatures are used.

### Experimental Example 2

### (1) Production of Carbonized Powder

In the same manner as in Experimental Example 1, 3 kinds of carbonized powders (A)-(C) having different carbonization temperatures were prepared. The carbonization temperature of (A)-(C) was 600° C., 900° C., 1150° C., respectively.

### (2) Production of Composition and Electromagnetic Wave Absorbing Plate

Carbonized powders (A) and (B) were mixed, and the mixture (total 130 parts by weight) and a novolac-type phenolic resin (“PHENOLITE J-325” manufactured by DIC, 100 parts by weight) were mixed in a mortar mixer in the same manner as in Experimental Example 1. The mixture was kneaded and formed in a two-axle roller, and heat-cured in an oven to produce electromagnetic wave absorbing plate (II). The mixing ratio of carbonized powders (A) and (B) was changed and 4 kinds of samples were obtained. The total of (A) and (B) was always 130 parts by weight.

In addition, in the same manner as in the production of electromagnetic wave absorbing plate (II) except that carbonized powders (A) and (C) were mixed, and the total 130 parts by weight and a novolac-type phenolic resin (100 parts by weight) were mixed, electromagnetic wave absorbing plate (III) was produced. Also, the mixing ratio of carbonized powders (A) and (C) was changed and 4 kinds of samples were obtained. The total of (A) and (C) was always 130 parts by weight.

The thickness of the obtained electromagnetic wave absorbing plates (II), (III) was 1.4 mm.

As mentioned above, in this Experimental Example, 4 kinds of electromagnetic wave absorbing plates (II) and (III) were produced by setting the total amount of the carbonized powder to 130 phr (parts by weight) and changing the mixing ratio (weight ratio) thereof. The weight ratios of the carbonized powders are shown in Table 2 and Table 3.

### (3) Measurement of Relative Dielectric Constant of Electromagnetic Wave Absorbing Plate

In the same manner as in Experimental Example 1, the relative dielectric constant of the obtained electromagnetic wave absorbing plate (thickness 1.4 mm, total amount of carbonized powders: 130 phr) was measured. The results are shown in Table 2, Table 3, FIG. 7.

### (4) First No-Reflection Curve

As explained in the “Description of Embodiments”, the first no-reflection curve was calculated. The first no-reflection curve is shown in FIG. 7.

### (5) Intersection Point of Curve of Graph Showing Relationship Between Real Part and Imaginary Part of Relative Dielectric Constant of Electromagnetic Wave Absorbing Plate, and First No-Reflection Curve

As explained in “Description of Embodiments”, based on the graph of FIG. 7 showing the relationship between the real part and the imaginary part of the relative dielectric constant of the electromagnetic wave absorbing plates (II) and (III), the d/λ values at an intersection point of a curve of the relative dielectric constant of the electromagnetic wave absorbing plates (II) and (III), and the first no-reflection curve (i.e., C_{II} and C_{III}) were calculated.

The results are shown in Table 2 and Table 3 as “intersection point”.

The weight ratio of the carbonized powder, and the relative dielectric constant of these electromagnetic wave absorbing plates at the intersection point are also shown in Table 2 and Table 3.

TABLE 2
Electromagnetic wave absorbing plate (II)

| | | weight ratio | | | relative | |
|---|---|---|---|---|---|---|
| | | (%) of | | total | dielectric | |
| | | carbonized | | amount of | constant | |
| | | powder | | carbonized | real | imaginary |
| | C_{II} | (A) | (B) | powder | part | part |
| No. 1 | — | 100 | 0 | 130 phr | 4.4 | 0.5 |
| No. 2 | — | 80 | 20 | 130 phr | 7.2 | 1.2 |
| No. 3 | — | 61 | 39 | 130 phr | 11.6 | 2.5 |
| No. 4 | — | 30 | 70 | 130 phr | 26.0 | 10.0 |
| inter- | 0.062 | 48 | 52 | 130 phr | 16.7 | 5.1 |
| section | | | | | | |
| point | | | | | | |

TABLE 3
Electromagnetic wave absorbing plate (III)

| | | | | | relative | |
|---|---|---|---|---|---|---|
| | | weight ratio | | total | dielectric | |
| | | (%) of | | amount of | constant | |
| | | carbonized | | carbonized | real | imaginary |
| | C_{III} | (A) | (C) | powder | part | part |
| No. 1 | — | 100 | 0 | 130 phr | 4.4 | 0.5 |
| No. 2 | — | 87 | 13 | 130 phr | 6.4 | 1.3 |
| No. 3 | — | 73 | 27 | 130 phr | 10.5 | 2.7 |
| No. 4 | — | 65 | 35 | 130 phr | 13.0 | 5.5 |
| inter- | 0.074 | 68 | 32 | 130 phr | 11.8 | 4.3 |
| section | | | | | | |
| point | | | | | | |

As shown in Table 2, C_{II} of the electromagnetic wave absorbing plate (II) containing 2 kinds of carbonized powders (A) and (B) is 0.062.

As shown in Table 3, C_{III} of the electromagnetic wave absorbing plate (III) containing 2 kinds of carbonized powders (A) and (C) is 0.074.

From these results, the d/λ value (i.e., C_{I}) in a non-reflective state of the electromagnetic wave absorbing plate (I) containing 3 kinds of carbonized powders (A)-(C) can be adjusted to fall between 0.062-0.074 by adjusting each weight ratio of the carbonized powders (A)-(B).

For example, C_{I}=0.065 can be realized by adjusting to carbonized powder (A):carbonized powder (B):carbonized powder (C)=36%:25%:39%. The weight ratio of the carbonized powder can be determined as follows.

The relationship between the weight ratio of each carbonized powder in the electromagnetic wave absorbing plate (I) containing 3 kinds of carbonized powders (A)-(C) and the relative dielectric constant is shown in Table 4. In addition, C_{I} in a non-reflective state and the relative dielectric constant value are also shown in Table 4.

TABLE 4
Electromagnetic wave absorbing plate (I)

| | | | | | total | relative | |
|---|---|---|---|---|---|---|---|
| | | weight ratio (%) | | | amount of | dielectric | |
| | | of carbonized | | | car- | constant | |
| | | powder | | | bonized | real | imaginary |
| | C_{I} | (A) | (B) | (C) | powder | part | part |
| No. 1 | — | 80 | 10 | 10 | 130 phr | 7.0 | 1.3 |
| No. 2 | — | 70 | 10 | 20 | 130 phr | 10.0 | 2.4 |
| No. 3 | — | 66 | 9 | 25 | 130 phr | 12.4 | 3.3 |
| No. 4 | — | 63 | 10 | 27 | 130 phr | 14.4 | 4.2 |
| No. 5 | — | 40 | 40 | 20 | 130 phr | 19.2 | 7.0 |
| inter- | 0.065 | 40 | 20 | 40 | 130 phr | 15.2 | 4.9 |
| section | | | | | | | |
| point | | | | | | | |

The formula for determining the relative dielectric constant from each weight ratio of the carbonized powders (A)-(C) is shown below.

The formula 5 and the formula 6 are used to determine the relative dielectric constant of the electromagnetic wave absorbing plate (II) containing two kinds of carbonized powders (A), (B) from the weight ratio of carbonized powder (B). In addition, the formula 11 and the formula 12 are used to determine the relative dielectric constant of the electromagnetic wave absorbing plate (III) containing two kinds of carbonized powders (A), (C) from the weight ratio of carbonized powder (C).

Therefore, besides these formulas, a formula showing the relationship between the weight ratio of the electromagnetic wave absorbing plate (I) containing 3 kinds of carbonized powders (A)-(C) and the relative dielectric constant was obtained as follows.

First, from the formula 5 and the formula 6, the relative dielectric constants (real part, imaginary part) when R_{B}=0 (carbonized powder (B) is 0%) were determined, these values taken as tentative relative dielectric constants when the carbonized powder (A) is 100(%). Using these values, the relationship between the weight ratio of carbonized powder (A) in the electromagnetic wave absorbing plate (II) and the relative dielectric constant due to carbonized powder (A) (namely, in the total relative dielectric constant, a part in which the carbonized powder (A) is involved) was determined.

To be specific, when carbonized powder (A) is 0%, the relative dielectric constant due to carbonized powder (A) is 0. Supposing that the relationship between the relative dielectric constant due to carbonized powder (A) and the weight ratio of the carbonized powder (A) is a linear function, a straight line of the linear function was determined from the relative dielectric constant (real part, imaginary part) values when the carbonized powder (A) is 100% or 0%. The straight lines are shown in FIG. 8.

The formulas of the aforementioned linear function are shown as the formula 17 and the formula 18. Here, R_{A} is a weight ratio (%) of the carbonized powder (A), and ∈′_{rA} and ∈″_{rA} each show the real part and the imaginary part of the relative dielectric constant due to the carbonized powder (A).

∈′_{rA}=0.0441R_{A} 17

∈″_{rA}=0.0053R_{A} 18

In the electromagnetic wave absorbing plate (II), the relative dielectric constant due to carbonized powder (B) is the value obtained by subtracting the relative dielectric constant (∈′_{rA}, ∈″_{rA}) due to carbonized powder (A) from the total relative dielectric constant (∈′_{rAB}, ∈″_{rAB}). This relationship can be shown by the formula 19 and the formula 20. Here, ∈′_{rB} and ∈″_{rB} are each a real part and an imaginary part of the relative dielectric constant due to carbonized powder (B) in the electromagnetic wave absorbing plate (II).

∈′_{rB}=∈′_{rAB}−∈′_{rA} 19

∈″_{rB}=∈″_{rAB}−∈″_{rA} 20

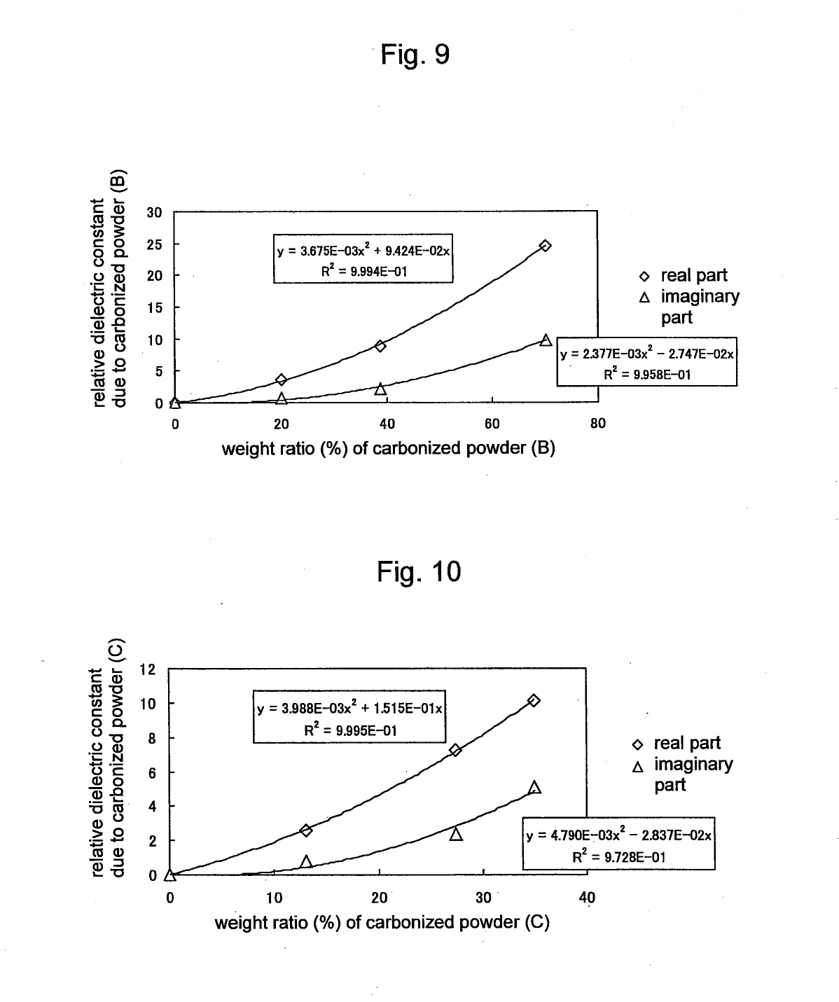

In addition, a graph (FIG. 9), showing the relationship between the weight ratio (%) of carbonized powder (B) in the electromagnetic wave absorbing plate (II) and the relative dielectric constant due to the carbonized powder (B), can be obtained by subtracting the relative dielectric constant (∈′_{rA}, ∈″_{rA}) due to carbonized powder (A) shown in FIG. 8 from the graph of FIG. 4. From these graphs, the formula 19 and the formula 20 can be each approximated by the formula 21 and the formula 22 containing R_{B} as a variable.

∈′_{rB}=0.003675R_{B}²+0.09424R_{B} 21

∈″_{rB}=0.002377R_{B}²+0.02747R_{B} 22

Similarly, in the electromagnetic wave absorbing plate (III), the relative dielectric constant due to carbonized powder (C) is the value obtained by subtracting the relative dielectric constant (∈′_{rA}, ∈″_{rA}) due to carbonized powder (A) from the total relative dielectric constant (∈′_{rAC}, ∈″_{rAC}). This relationship can be shown by the formula 23 and the formula 24. Here, ∈′_{rC} and ∈″_{rC} are each a real part and an imaginary part of the relative dielectric constant due to carbonized powder (C) in the electromagnetic wave absorbing plate (III).

∈′_{rC}=∈′_{rAC}−∈′_{rA} 23

∈″_{rC}=∈″_{rAC}−∈″_{rA} 24

In addition, a graph (FIG. 10), showing the relationship between the weight ratio (%) of carbonized powder (C) in the electromagnetic wave absorbing plate (III) and the relative dielectric constant due to the carbonized powder (C), can be obtained by subtracting the relative dielectric constant (∈′_{rA}, ∈″_{rA}) due to carbonized powder (A) shown in FIG. 8 from the graph of FIG. 5. From these graphs, the formula 23 and the formula 24 can be each approximated by the formula 25 and the formula 26 containing R_{C} as a variable.

∈′_{rC}=0.003988R_{C}²+0.1515R_{C} 25

∈″_{rC}=0.00479R_{C}²−0.02837R_{C} 26

When the real part and the imaginary part of the relative dielectric constant of the electromagnetic wave absorbing plate (I) containing 3 kinds of carbonized powders (A), (B), (C) are ∈′_{rABC} and ∈″_{rABC}, respectively, these can be determined as the total of the aforementioned ∈′_{rA}, ∈′_{rA} and ∈′_{rA}, and the total of ∈″_{rA}, ∈″_{rA} and ∈″_{rA} (formula 27 and formula 28).

∈′_{rABC}=∈′_{rA}+∈′_{rB}+∈′_{rC} 27

∈″_{rABC}=∈″_{rA}+∈″_{rB}+∈″_{rC} 28

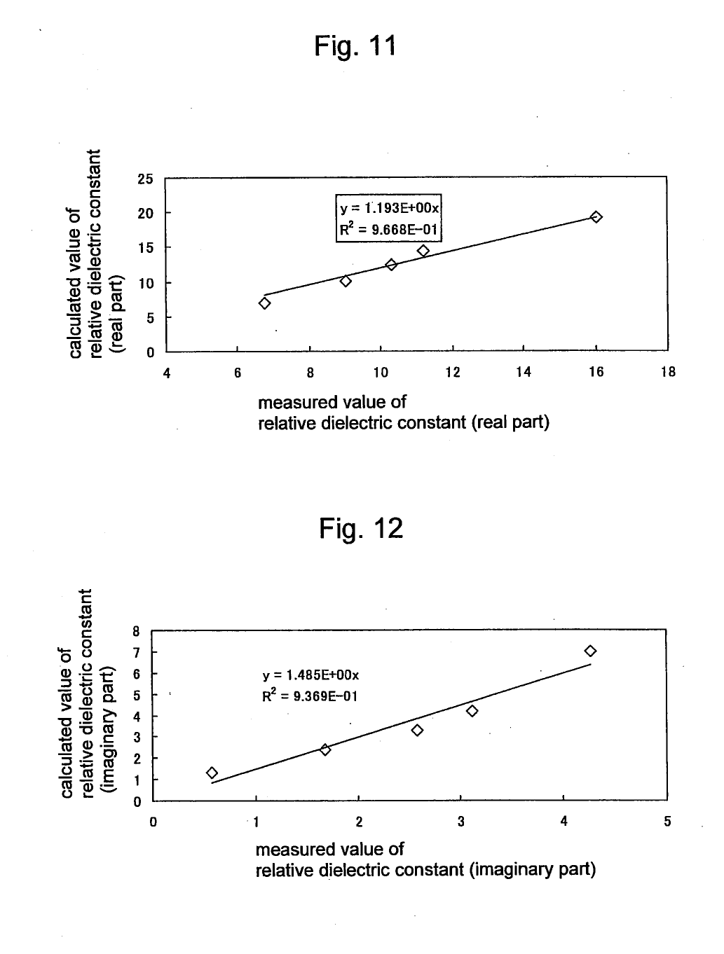

The calculated values of the relative dielectric constant were determined by inserting the weight ratios of the carbonized powders (A)-(C) in Nos. 1-5 in Table 4 into the formula 27 and the formula 28. Graphs (FIG. 11 and FIG. 12) were formed, which show the relationship between the thus-determined calculated value of the relative dielectric constant of the electromagnetic wave absorbing plate (I) and the measured values thereof.

It is appreciated from the graphs of FIG. 11 and FIG. 12 that a good correlation stands between the measured values of the relative dielectric constant and the calculated values of the relative dielectric constant obtained from the formula 27 and the formula 28. This relationship is shown by the formula 29 and the formula 30. Here, ∈′ᵣ and ∈″ᵣ are the real part and the imaginary part, respectively, of the measured values of the relative dielectric constant.

∈′_{rABC}=1.193∈′ᵣ 29

∈″_{rABC}=1.485∈″ᵣ 30

The formula 31 and the formula 32 can be obtained from the formula 29, the formula 30, and the formula 3, the formula 4.

$$\begin{matrix}{ɛ}_{r ABC}^{′} = 0.08911 {( \frac{d}{λ} )}^{- 1.9453} & 31 \\ {ɛ}_{r ABC}^{″} = 0.4492 {( \frac{d}{λ} )}^{- 1.0101} & 32\end{matrix}$$

The formula 33 and the formula 34 can be obtained from the formula 31, the formula 32, the formula 17, the formula 18, the formula 21, the formula 22, the formula 25, the formula 26, the formula 27, the formula 28.

$$\begin{matrix}0.08911 {( \frac{d}{λ} )}^{- 1.9453} = 0.0441 {R}_{A} + 0.003675 {R}_{B}^{2} + 0.09424 {R}_{B} + 0.003988 {R}_{C}^{2} + 0.1515 {R}_{C} & 33 \\ 0.4492 {( \frac{d}{λ} )}^{- 1.0101} = 0.0053 {R}_{A} + 0.002377 {R}_{B}^{2} - 0.02747 {R}_{B} + 0.00479 {R}_{C}^{2} - 0.02837 {R}_{C} & 34\end{matrix}$$

In the electromagnetic wave absorbing plate (I), since the total of the weight ratio of the carbonized powders (A)-(C) is 100%, the formula 35 stands.

R_{A}+R_{B}+R_{C}=100 35

In the electromagnetic wave absorbing plate (I), the weight ratios R_{A}, R_{B} and R_{C} of the carbonized powders (A)-(C) relative to the object d/λ can be determined by solving the simultaneous equations of the formula 33-the formula 35.

For example, the weight ratio of the carbonized powders (A)-(C) to achieve d/λ=0.065 are R_{A}=36%, R_{C}=25%, R_{D}=39% from the simultaneous equations of the formula 33-the formula 35 as shown in Table 4.

### Experimental Example 3

### (1) Production of Carbonized Powder

(a) 600° C., (b) 670° C., (c) 900° C. were selected from the above-mentioned carbonization temperatures (a)-(d), and 3 to kinds of carbonized powders (a), (b), (c) were prepared.

### (2) Production of Composition and Electromagnetic Wave Absorbing Plate

Carbonized powders (a) and (b) were mixed, and the mixture (total 130 parts by weight) and a novolac-type phenolic resin (“PHENOLITE J-325” manufactured by DIC, 100 parts by weight) were mixed in a mortar mixer in the same manner as in Experimental Example 1. The mixture was kneaded and formed in a two-axle roller, and heat-cured in an oven to produce electromagnetic wave absorbing plate (IIβ). The mixing ratio of carbonized powders (a) and (b) was changed and 4 kinds of samples were obtained. The total of (a) and (b) was always 130 parts by weight.

In addition, electromagnetic wave absorbing plate (IIIβ) was produced, in the same manner as in the production of electromagnetic wave absorbing plate (IIβ) except that carbonized powders (a) and (c) were mixed, and the total 130 parts by weight and a novolac-type phenolic resin (100 parts by weight) were mixed. Also, the mixing ratio of carbonized powders (a) and (c) was changed and 4 kinds of samples were obtained. The total of (a) and (c) was always 130 parts by weight.

The thickness of the obtained electromagnetic wave absorbing plates (IIβ), (IIIβ) was 1.4 mm.

In this Experimental Example, electromagnetic wave absorbing plates (IIβ) and (IIIβ) were produced by changing the weight ratio (mixing ratio) of each carbonized powder while maintaining the total amount of the carbonized powder of 130 phr. The weight ratios of the carbonized powders are shown in Table 5 and Table 6.

### (3) Measurement of Relative Dielectric Constant of Electromagnetic Wave Absorbing Plate

In the same manner as in Experimental Example 1, the relative dielectric constant of the obtained electromagnetic wave absorbing plate (thickness 1.4 mm, total amount of carbonized powders: 130 phr) was measured. The results are shown in Table 5, Table 6, and the graph of FIG. 16.

In the graph of FIG. 16, the curve of electromagnetic wave absorbing plate (III) containing carbonized powder (A) with a carbonization temperature of 600° C. and carbonized powder (C) with a carbonization temperature of 1150° C. in the above-mentioned Experimental Example 2 is added as a curve of electromagnetic wave absorbing plate (IVβ) for reference.

### (4) First No-Reflection Curve

As explained in the “Description of Embodiments”, the first no-reflection curve was calculated. The first no-reflection curve is shown in the graph of FIG. 16.

### (5) Intersection Point of Graph Showing Relationship Between Real Part and Imaginary Part of Relative Dielectric Constant of Electromagnetic Wave Absorbing Plate, and First No-Reflection Curve

As explained in “Description of Embodiments”, based on the graph of FIG. 16 showing the relationship between the real part and the imaginary part of the relative dielectric constant of the electromagnetic wave absorbing plates (IIβ) and (IIIβ), the d/λ values (i.e., C_{IIβ} and C_{IIIβ}) at an intersection point of a curve of the relative dielectric constant of the electromagnetic wave absorbing plates (IIβ) and (IIIβ), and the first no-reflection curve were calculated.

The results are shown in Table 5 and Table 6. The weight ratio of the carbonized powder, and the relative dielectric constant of these electromagnetic wave absorbing plates at the intersection point are also shown in Table 5 and Table 6.

TABLE 5
Electromagnetic wave absorbing plate (IIβ)

| | | weight ratio | | | relative | |
|---|---|---|---|---|---|---|
| | | (%) of | | total | dielectric | |
| | | carbonized | | amount of | constant | |
| | | powder | | carbonized | real | imaginary |
| | C_{IIβ} | (a) | (b) | powder | part | part |
| No. 1 | | 100 | 0 | 130 phr | 4.5 | 0.6 |
| No. 2 | | 90 | 10 | 130 phr | 5.6 | 1.0 |
| No. 3 | | 80 | 20 | 130 phr | 6.6 | 1.5 |
| No. 4 | | 50 | 50 | 130 phr | 9.8 | 5.0 |
| No. 5 | | 0 | 100 | 130 phr | 19.2 | 15.5 |
| inter- | 0.087 | 59.6 | 40.4 | 130 phr | 8.7 | 3.7 |
| section | | | | | | |
| point | | | | | | |

TABLE 6
Electromagnetic wave absorbing plate (IIIβ)

| | | weight | | | relative | |
|---|---|---|---|---|---|---|
| | | ratio (%) of | | total | dielectric | |
| | | carbonized | | amount of | constant | |
| | | powder | | carbonized | real | imaginary |
| | C_{IIIβ} | (a) | (c) | powder | part | part |
| No. 1 | | 100 | 0 | 130 phr | 4.4 | 0.5 |
| No. 2 | | 80 | 20 | 130 phr | 7.2 | 1.2 |
| No. 3 | | 61 | 39 | 130 phr | 11.6 | 2.5 |
| No. 4 | | 30 | 70 | 130 phr | 26.0 | 10.0 |
| inter- | 0.062 | 48 | 52 | 130 phr | 16.7 | 5.1 |
| section | | | | | | |
| point | | | | | | |

As shown in Table 5, C_{IIβ} of the electromagnetic wave absorbing plate (IIβ) containing 2 kinds of carbonized powders (a) and (b) is 0.087.

As shown in Table 6, C_{IIIβ} of the electromagnetic wave absorbing plate (IIIβ) containing 2 kinds of carbonized powders (a) and (c) is 0.062.

From these results, the d/λ value (i.e., C_{Iβ1}) in a non-reflective state of the electromagnetic wave absorbing plate (Iβ1) containing 3 kinds of carbonized powders (a), (b), (c) can be adjusted to fall between 0.062-0.087 by adjusting each weight ratio of carbonized powders (a), (b), (c).

Similarly, the d/λ value (i.e., C_{Iβ2}) in a non-reflective state of the electromagnetic wave absorbing plate (I) containing 3 kinds of carbonized powders (a), (c) and (d) can be adjusted to fall between 0.062-0.074 by adjusting each weight ratio of the carbonized powders (a), (c) and (d).

For example, C_{Iβ1}=0.08 can be realized by adjusting to carbonized powder (a):carbonized powder (b):carbonized powder (c)=68%:9%:23%. The weight ratio of the carbonized powder can be determined as follows.

The relationship between the weight ratio of each carbonized powder in the electromagnetic wave absorbing plate (Iβ1) containing 3 kinds of carbonized powders (a)-(c) and the relative dielectric constant is shown in Table 7. In addition, C_{Iβ1} in a non-reflective state and the relative dielectric constant value are also shown in Table 7.

TABLE 7
Electromagnetic wave absorbing plate (Iβ1)

| | | weight | | | | relative | |
|---|---|---|---|---|---|---|---|
| | | ratio (%) of | | | total | dielectric | |
| | | carbonized | | | amount of | constant | |
| | | powder | | | carbonized | real | imaginary |
| | C_{Iβ1} | (a) | (b) | (c) | powder | part | part |
| No. 1 | | 47.0 | 43.0 | 10.0 | 130 phr | 13.0 | 4.0 |
| No. 2 | | 35.0 | 45.0 | 20.0 | 130 phr | 18.9 | 8.7 |
| No. 3 | | 19.0 | 41.0 | 40.0 | 130 phr | 25.0 | 10.8 |
| No. 4 | | 20.0 | 10.0 | 70.0 | 130 phr | 28.9 | 13.4 |
| inter- | 0.08 | 68.0 | 9.0 | 23.0 | 130 phr | 10.2 | 3.9 |
| section | | | | | | | |
| point | | | | | | | |

The formula for determining the relative dielectric constant from each weight ratio of the carbonized powders (a)-(c) is shown below.

The aforementioned formula 5β, the formula 6β, and the formula 5, the formula 6 are used to determine the relative dielectric constant of the electromagnetic wave absorbing plates (IIβ) and (IIIβ) containing two kinds of carbonized powders, from the weight ratio of carbonized powder (b) or (c).

Therefore, besides these formulas, a formula showing the relationship between the weight ratio of the electromagnetic wave absorbing plate (Iβ1) containing 3 kinds of carbonized powders (a)-(c) and the relative dielectric constant is necessary.

First, from the formula 5β and the formula 6β, the relative dielectric constants (real part, imaginary part) when R_{b}=0 (carbonized powder (b) is 0%) were determined, these values taken as tentative relative dielectric constants when the carbonized powder (a) is 100(%). Using these values, the relationship between the weight ratio of carbonized powder (a) in the electromagnetic wave absorbing plate (IIβ) and the relative dielectric constant due to carbonized powder (a) was determined.

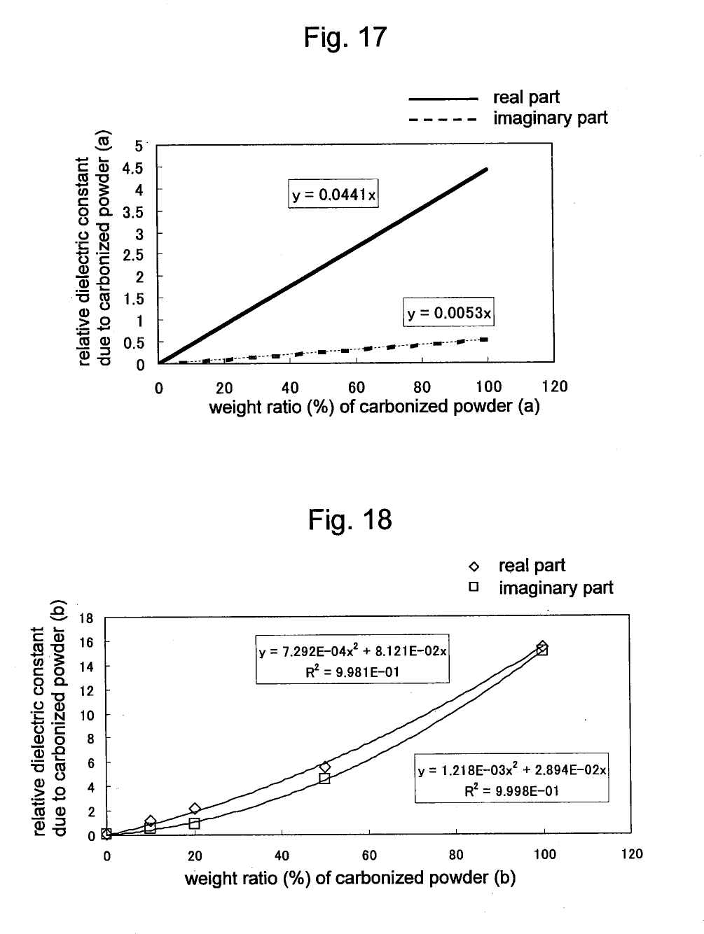

To be specific, when carbonized powder (a) is 0%, the relative dielectric constant due to carbonized powder (a) is 0. Supposing that the relationship between the relative dielectric constant due to carbonized powder (a) and the weight ratio of the carbonized powder (a) is a linear function, the linear functions were determined from the relative dielectric constant (real part, imaginary part) values when the carbonized powder (a) is 100% or 0%. The straight lines are shown in FIG. 17.

The formulas of the aforementioned linear function are shown as the formula 17β and the formula 18β. Here, Rₐ is a weight ratio (%) of the carbonized powder (a), and ∈′ᵣₐ and ∈″ᵣₐ each show the real part and the imaginary part of the relative dielectric constant due to the carbonized powder (a).

∈′ᵣₐ=0.0441Rₐ 17β

∈″ᵣₐ=0.005313Rₐ 18β

In the electromagnetic wave absorbing plate (IIβ), the relative dielectric constant due to carbonized powder (b) is the value obtained by subtracting the relative dielectric constant (∈′ᵣₐ, ∈″ᵣₐ) due to carbonized powder (a) from the total relative dielectric constant (∈′_{rab}, ∈″_{rab}). This relationship can be shown by the formula 19β and the formula 20β. Here, ∈′_{rb} and ∈″_{rb} are each a real part and an imaginary part of the relative dielectric constant due to carbonized powder (b) in the electromagnetic wave absorbing plate (IIβ).

∈′_{rb}=∈′_{rab}−∈′ᵣₐ 19β

∈″_{rb}=∈′_{rab}−∈″ᵣₐ 20β

In addition, a curve of a graph (FIG. 18) showing the relationship between the weight ratio (%) of carbonized powder (b) in the electromagnetic wave absorbing plate (IIβ) and the relative dielectric constant due to the carbonized powder (b) can be obtained by subtracting [the relative dielectric constant (∈′ᵣₐ, ∈″ᵣₐ) due to carbonized powder (a)] shown in the graph of FIG. 17 from the curve shown in the graph of FIG. 13.

From these graphs, the formula 19β and the formula 20β can be each approximated by the formula 21β and the formula 22β containing R_{b} as a variable.

∈′_{rb}=0.0007292R_{b}²+0.08121R_{b} 21β

∈″_{rb}=0.001218R_{b}²+0.02894R_{b} 22β

Similarly, in the electromagnetic wave absorbing plate (IIIβ), the relative dielectric constant due to carbonized powder (c) is the value obtained by subtracting the relative dielectric constant (∈′ᵣₐ, ∈″ᵣₐ) due to carbonized powder (a) from the total relative dielectric constant (∈′_{rac}, ∈″_{rac}). This relationship can be shown by the formula 23 and the formula 24. Here, ∈′_{rc} and ∈″_{rc} are each a real part and an imaginary part of the relative dielectric constant due to carbonized powder (c) in the electromagnetic wave absorbing plate (IIIβ).

Similarly, in the electromagnetic wave absorbing plate (IIIβ), the relative dielectric constant due to carbonized powder (c) is the value obtained by subtracting the relative dielectric constant (∈′ᵣₐ, ∈″ᵣₐ) due to carbonized powder (a) from the total relative dielectric constant (∈′_{rac}, ∈″_{rac}). This relationship can be shown by the formula 23β and the formula 24β. Here, ∈′_{rc} and ∈″_{rc} are each a real part and an imaginary part of the relative dielectric constant due to carbonized powder (c) in the electromagnetic wave absorbing plate (IIIβ).

∈′_{rc}=∈′_{rac}−∈′ᵣₐ 23β

∈″_{rc}=∈″_{rac}−∈″ᵣₐ 24β

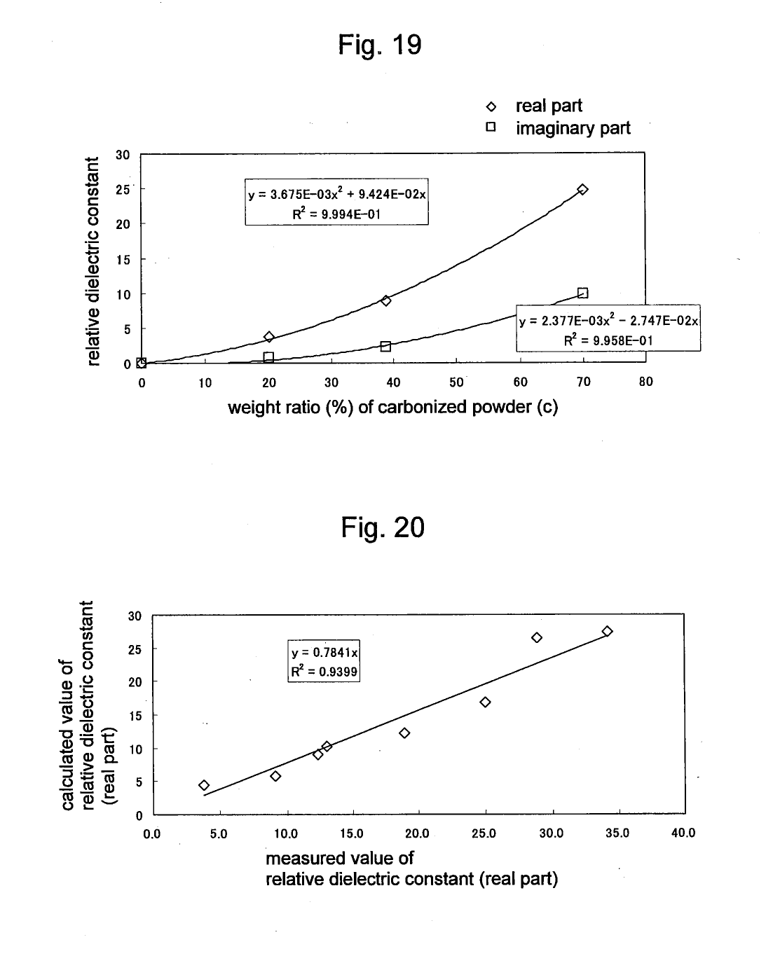

In addition, a curve of a graph (FIG. 19) can be obtained, showing the relationship between the weight ratio (%) of carbonized powder (c) in the electromagnetic wave absorbing plate (IIIβ) and the relative dielectric constant due to the carbonized powder (c), by subtracting [the relative dielectric constant (∈′ᵣₐ, ∈″ᵣₐ) due to carbonized powder (a)] shown in the graph of FIG. 17 from the curve shown in the graph of FIG. 14. From these graphs, the formula 23β and the formula 24β can be each approximated by the formula 25β and the formula 26β containing R_{C} as a variable.

∈′_{rc}=0.003675R_{c}²+0.09424R_{c} 25β

∈″_{rc}=0.002377R_{c}²−0.02747R_{c} 26β

When the real part and the imaginary part of the relative dielectric constant of the electromagnetic wave absorbing plate (Iβ1) containing 3 kinds of carbonized powders (a), (b), (c) are ∈′_{rabc} and ∈″_{rabc}, respectively, these can be determined as the total of the aforementioned ∈′ᵣₐ, ∈′_{rb} and ∈′_{rc}, and the total of ∈″ᵣₐ, ∈″_{rb} and ∈″_{rc} (formula 27β and formula 28β).

∈′_{rabc}=∈′ᵣₐ+∈′_{rb}+∈′_{rc} 27β

∈″_{rabc}=∈″ᵣₐ+∈″_{rb}+∈″_{rc} 28β

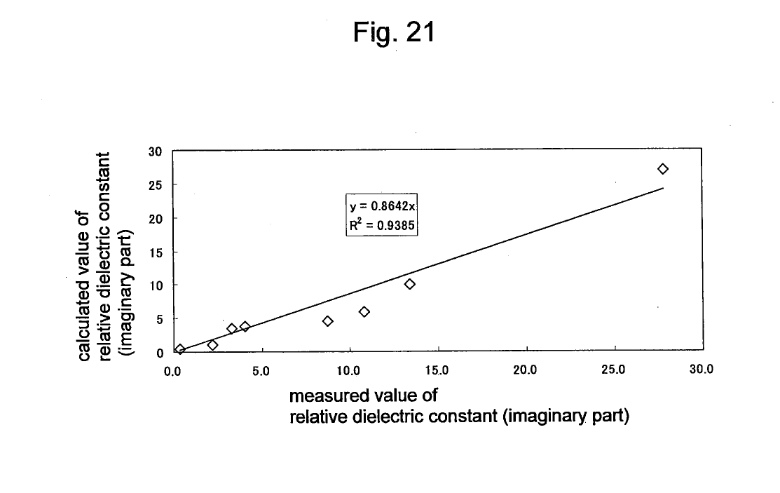

The calculated values of the relative dielectric constant were determined by inserting the weight ratios of the carbonized powders (a)-(c) in Nos. 1-4 in Table 7 into the formula 27β and the formula 28β. Graphs (FIG. 20 and FIG. 21), showing the relationship between the thus-determined calculated value of the relative dielectric constant of the electromagnetic wave absorbing plate (Iβ1) and the measured values thereof, were formed.

It is appreciated from the graphs of FIG. 20 and FIG. 21 that a good correlation stands between the measured values of the relative dielectric constant and the calculated values of the relative dielectric constant obtained from the formula 27β and the formula 28β. This relationship is shown by the formula 29β and the formula 30β. Here, ∈′ᵣ and ∈″ᵣ are the real part and the imaginary part, respectively, of the measured values of the relative dielectric constant.

∈′_{rabc}=0.7841∈′ᵣ 29β

∈″_{rabc}=0.8642∈″ᵣ 30β

The formula 31β and the formula 32β can be obtained from the above-mentioned formula 29β, formula 30β, and the above-mentioned formula 3, formula 4.

$$\begin{matrix}{ɛ}_{r abc}^{′} = 0.05857 {( \frac{d}{λ} )}^{- 1.9453} & 31 β \\ {ɛ}_{r abc}^{″} = 0.2662 {( \frac{d}{λ} )}^{- 1.0101} & 32 β\end{matrix}$$

The following formula 33β and formula 34β can be obtained from the above-mentioned formula 31β and formula 32β, the formula 17β and the formula 18β, the formula 21β and the formula 22β, the formula 25β and the formula 26β, and the formula 27β and the formula 28β.

$$\begin{matrix}0.05857 {( \frac{d}{λ} )}^{- 1.9453} = 0.0441 {R}_{a} + 0.0007292 {R}_{b}^{2} + 0.0812 {R}_{b} + 0.003675 {R}_{c}^{2} + 0.0942 {R}_{c} & 33 β \\ 0.2662 {( \frac{d}{λ} )}^{- 1.0101} = 0.0053 {R}_{a} + 0.001218 {R}_{b}^{2} - 0.02894 {R}_{b} + 0.002377 {R}_{c}^{2} - 0.02747 {R}_{c} & 34 β\end{matrix}$$

Since the total of the weight ratio of the carbonized powders (a)-(c) in the electromagnetic wave absorbing plate (Iβ1) is 100%, the formula 35β stands.

Rₐ+R_{b}+R_{c}=100 35β

In the electromagnetic wave absorbing plate (Iβ1), the weight ratios R_{A}, R_{B} and R_{C} of the carbonized powders (a)-(c) relative to the object d/λ can be determined by solving the simultaneous equations of the formula 33β, the formula 34β, the formula 35β.

For example, the weight ratio of the carbonized powders (a)-(c) to achieve d/λ=0.08 are Rₐ=68%, R_{b}=9%, R_{c}=23% from the simultaneous equations of the formula 33β, the formula 34β, the formula 35β as shown in Table 7.

As explained above, the d/λ value (i.e., C_{Iβ1}) in a non-reflective state of the electromagnetic wave absorbing plate (Iβ1) containing 3 kinds of carbonized powders (a), (b) and (c) can be adjusted to fall between 0.062-0.087 by adjusting each weight ratio of the carbonized powders (a), (b) and (c).

An electromagnetic wave absorbing plate containing 3 kinds of [carbonized powder (a), carbonization temperature 600° C.], [carbonized powder (c), carbonization temperature 900° C.], and [carbonized powder (d), carbonization temperature 1150° C.] is as shown in the above-mentioned Experimental Example 2.

For example, d/λ=0.065 can be realized by adjusting to [carbonized powder (a):carbonized powder (c):carbonized powder (d))=[36%:25%:39%].

### INDUSTRIAL APPLICABILITY

According to the present invention, the d/λ value in a non-reflective state of the electromagnetic wave absorbing plate can be adjusted to fall within the predetermined range rather than one point. Particularly, when one kind of a plant material is used, the plant material is carbonized at different carbonization temperatures to obtain plural kinds of carbonized powders, and the carbonized powders are mixed to form an electromagnetic wave absorbing plate, a d/λ value in a reflection state of the electromagnetic wave absorbing plate can be changed by adjusting each weight ratio. Therefore, plural kinds of plant materials do not need to be preserved in stock, which is economical.

Where a numerical limit or range is stated herein, the endpoints are included. Also, all values and subranges within a numerical limit or range are specifically included as if explicitly written out.

As used herein the words “a” and “an” and the like carry the meaning of “one or more.”

Obviously, numerous modifications and variations of the present invention are possible in light of the above teachings. It is therefore to be understood that, within the scope of the appended claims, the invention may be practiced otherwise than as specifically described herein.

All patents and other references mentioned above are incorporated in full herein by this reference, the same as if set forth at length.

1. A composition for an electromagnetic wave absorbing plate, which comprises a carbonized powder and a resin, wherein a plurality of kinds of carbonized powders obtained by carbonizing a plant material at different carbonization temperatures are dispersed in the resin.

2. The composition according to claim 1, wherein each of said plurality of kinds of carbonized powders has a weight ratio adjusted according to a d/λ value in a non-reflective state, wherein d is the thickness of an electromagnetic wave absorbing plate formed from said composition, and λ is the wavelength of an electromagnetic wave to be absorbed by said electromagnetic wave absorbing plate, such that said electromagnetic wave absorbing plate is in the non-reflective state.

3. The composition according to claim 1, wherein said plurality of kinds of carbonized powders are 3 kinds of carbonized powders obtained by carbonizing a plant material at the carbonization temperatures of the following (A)-(C):
(A) less than 850° C.,
(B) not less than 850° C. and less than 950° C., and
(C) not less than 950° C.

4. The composition according to claim 3, wherein the carbonization temperatures of said (A)-(C) are
(A) not less than 400° C. and not more than 800° C.,
(B) not less than 850° C. and not more than 930° C., and
(C) not less than 950° C. and not more than 3000° C.

5. The composition according to claim 1, wherein said plural kinds of carbonized powders are 3 or 4 kinds of carbonized powders selected from 4 kinds of carbonized powders obtained by carbonizing a plant material at the carbonization temperatures of the following (a)-(d):
(a) not less than 550° C. and less than 650° C.,
(b) not less than 650° C. and less than 800° C.,
(c) not less than 800° C. and less than 1000° C., and
(d) not less than 1000° C. and not more than 1200° C.

6. The composition according to claim 5, wherein the carbonization temperatures of said (a)-(d) are
(a) not less than 550° C. and not more than 630° C.,
(b) not less than 650° C. and not more than 730° C.,
(c) not less than 850° C. and less than 1000° C., and
(d) not less than 1100° C. and not more than 1200° C.

7. The composition according to claim 1, wherein said plant material is humus.

8. An electromagnetic wave absorbing plate formed from the composition according to claim 1.

9. The electromagnetic wave absorbing plate according to claim 8, wherein the electromagnetic wave to be absorbed by the electromagnetic wave absorbing plate has a wavelength λ of 100 μm to 1 m.

10. A method of producing an electromagnetic wave absorbing plate, comprising:
mixing a resin and a plurality of kinds of carbonized powders obtained by carbonizing a plant material at different carbonization temperatures to give a composition wherein the plurality of kinds of carbonized powders are dispersed in the resin; and forming said composition to give the electromagnetic wave absorbing plate.

11. The method according to claim 10, wherein a weight ratio of each of said plurality of kinds of carbonized powders is adjusted according to a d/λ value in a non-reflective state, wherein d is the thickness of an electromagnetic wave absorbing plate formed from said composition, and λ is the wavelength of an electromagnetic wave to be absorbed by said electromagnetic wave absorbing plate, such that said electromagnetic wave absorbing plate is in the non-reflective state.

12. The method according to claim 10, wherein said plural kinds of carbonized powders are 3 kinds of carbonized powders obtained by carbonizing a plant material at the carbonization temperatures of the following (A)-(C):
(A) less than 850° C.,
(B) not less than 850° C. and less than 950° C., and
(C) not less than 950° C.

13. The method according to claim 12, wherein the carbonization temperatures of said (A)-(C) are
(A) not less than 400° C. and not more than 800° C.,
(B) not less than 850° C. and not more than 930° C., and
(C) not less than 950° C. and not more than 3000° C.

14. The method according to claim 10, wherein the said kinds of carbonized powders are 3 or 4 kinds of carbonized powders selected from 4 kinds of carbonized powders obtained by carbonizing a plant material at the carbonization temperatures of the following (a)-(d):
(a) not less than 550° C. and less than 650° C.,
(b) not less than 650° C. and less than 800° C.,
(c) not less than 800° C. and less than 1000° C., and
(d) not less than 1000° C. and not more than 1200° C.

15. The method according to claim 14, wherein the carbonization temperatures of said (a)-(d) are
(a) not less than 550° C. and not more than 630° C.,
(b) not less than 650° C. and not more than 730° C.,
(c) not less than 850° C. and less than 1000° C., and
(d) not less than 1100° C. and not more than 1200° C.

16. The method according to claim 10, wherein an electromagnetic wave to be absorbed by said electromagnetic wave absorbing plate has a wavelength λ of 100 μm to 1 m.

17. The method according to claim 10, wherein the wavelength λ of said electromagnetic wave is fixed at a given value, and
the thickness d of an electromagnetic wave absorbing plate to achieve a non-reflective state relative to said wavelength λ is changed by changing each weight ratio of said 3 kinds of carbonized powders.

18. The method according to claim 10, wherein the thickness d of an electromagnetic wave absorbing plate is fixed at a given value, and
the wavelength λ of said electromagnetic wave which achieves a non-reflective state relative to said thickness d is changed by changing each weight ratio of said 3 kinds of carbonized powders.

19. The method according to claim 10, wherein said plant material is humus.
